(19) United States
(12) Patent Application Publication
(10) Pub. No.: US 2026/0323816 A1
(43) Pub. Date: Oct. 15, 2026

(54) WIRING BOARD AND IMAGE DISPLAY DEVICE

(71) Applicant: DAI NIPPON PRINTING CO., LTD., Tokyo-to (JP)

(72) Inventors: Seiji TAKE, Tokyo-to (JP); Kazuki KINOSHITA, Tokyo-to (JP); Yuya AIDA, Tokyo-to (JP); Keita IIMURA, Tokyo-to (JP); Masao FUKUSHIMA, Tokyo-to (JP); Masashi SAKAKI, Tokyo-to (JP); Shotaro HOSODA, Tokyo-to (JP); Hiroshi YAMAMOTO, Tokyo-to (JP); Akihiro KUSAHARA, Tokyo-to (JP)

(73) Assignee: DAI NIPPON PRINTING CO., LTD., Tokyo-to (JP)

(21) Appl. No.: 19/484,191

(22) PCT Filed: May 16, 2024
(86) PCT No.: PCT/JP2024/018092

§ 371 Date: Nov. 13, 2025

(30) Foreign Application Priority Data
May 16, 2023 (JP) 2023-080982

(51) Int. Cl. H05K 1/02; H01Q 1/12; H01Q 21/00

(52) U.S. Cl. CPC H05K 1/0274; H01Q 1/1271; H01Q 21/00; H05K 2201/10128

(57) ABSTRACT

A wiring board includes a substrate having a first surface and a second surface positioned opposite to the first surface, a primer layer disposed on the first surface of the substrate, and a mesh wiring layer disposed on the primer layer. The substrate has transparency. The mesh wiring layer includes a first dark color layer disposed on the primer layer, a first metal layer disposed on the first dark color layer, and a second metal layer disposed on the first metal layer. The first dark color layer has a surface roughness Sa greater than or equal to 5 nm and less than or equal to 200 nm.

### TECHNICAL FIELD

The present invention relates to a wiring board and an image display device.

### BACKGROUND ART

Mobile terminal devices such as smartphones, tablets, or smart glasses (for example, augmented reality (AR) or mixed reality (MR)) are currently undergoing advancements in functionality, as well as reductions in size, thickness, and weight. These mobile terminal devices use multiple communication bands, and are thus to include multiple antennas corresponding to communication bands. For example, each mobile terminal device includes multiple antennas such as a telephone antenna, a wireless fidelity (Wi-Fi) antenna, a third generation (3G) antenna, a fourth generation (4G) antenna, a fifth generation (5G) antenna, a long term evolution (LTE) antenna, a Bluetooth (registered trademark) antenna, and a near field communication (NFC) antenna. However, the size reduction of mobile terminal devices limits the space for receiving antennas, and reduces the freedom of antenna design. Moreover, antennas installed in a limited space may not necessarily have sufficiently high reception sensitivity.

To address this, a film antenna installable in a display area of a mobile terminal device or transmission areas of smart glasses has been developed. This film antenna includes an antenna pattern disposed on a transparent substrate. The antenna pattern is formed from a conductor mesh layer including conductors at each of which an opaque electrically conductive layer is formed, and a large number of apertures in each of which the opaque electrically conductive layer is not formed.

### CITATION LIST

### Patent Literature

Patent Literature 1: Japanese Unexamined Patent Application Publication No. 2011-66610

### SUMMARY OF INVENTION

### Technical Problem

For example, an existing film antenna includes one or more mesh antennas installed on a transparent substrate, and an area where an antenna pattern is formed and an area where the antenna pattern is not formed are both formed on the transparent substrate. In this structure, the area where the antenna pattern is not formed unintentionally enhances the visibility of the area where the antenna pattern is formed. To address this, a technology of lowering the visibility of a wiring pattern such as an antenna pattern has been awaited.

In addition, for example, to reduce separation of an antenna pattern from a transparent substrate, a film antenna that improves adhesion between the transparent substrate and the antenna pattern has been awaited.

### Solution to Problem

An embodiment of the present invention provides a wiring board and an image display device that include a mesh wiring layer that is less visually discernible and in which adhesion between a substrate and the mesh wiring layer is improved.

An embodiment of the present invention further provides a wiring board and an image display device that include a mesh wiring layer that is less visually discernible.

Embodiments of the present disclosure relate to [1] to [9], below.

[1] A wiring board, comprising:
a substrate having a first surface and a second surface positioned opposite to the first surface;
a primer layer disposed on the first surface of the substrate; and
a mesh wiring layer disposed on the primer layer,
wherein the substrate has transparency,
wherein the mesh wiring layer includes
   a first dark color layer disposed on the primer layer,
   a first metal layer disposed on the first dark color layer, and
   a second metal layer disposed on the first metal layer, and
wherein the first dark color layer has a surface roughness Sa greater than or equal to 5 nm and less than or equal to 200 nm.

[2] The wiring board according to [1], further comprising:
a second dark color layer covering the mesh wiring layer,
wherein the second dark color layer has a surface roughness Sa greater than or equal to 5 nm and less than or equal to 100 nm.

[3] The wiring board according to [1] or [2],
wherein the first metal layer and the second metal layer have different crystal properties, and the second metal layer has a crystal property in which a diffraction angle 2θ of a (111) plane measured using Cu Kα radiation as an X-ray source is less than 43.4°.

[4] The wiring board according to any one of [1] to [3],
wherein the substrate has a dielectric loss tangent less than or equal to 0.002.

[5] The wiring board according to any one of [1] to [4],
wherein an increased rate of resistance of the mesh wiring layer is less than or equal to 20% when an operation including bending the wiring board 180° along a circumference of a cylinder with a diameter of 1 mm and then flattening the wiring board is performed 100 times.

[6] The wiring board according to any one of [1] to [5],
wherein the wiring board has a function of transmitting and receiving millimeter waves, and the mesh wiring layer serves as an array antenna.

[7] The wiring board according to any one of [1] to [6],
wherein at least one dummy wiring layer electrically separate from the mesh wiring layer is disposed around the mesh wiring layer.

[8] The wiring board according to [7],
wherein the at least one dummy wiring layer includes a plurality of dummy wiring layers, and the mesh wiring layer and the plurality of dummy wiring layers have aperture ratios that increase stepwise from the mesh wiring layer toward the plurality of dummy wiring layers, in a direction extending away from the mesh wiring layer.

[9] An image display device, comprising:
the wiring board according to any one of [1] to [8]; and
a display device laminated on the wiring board.

The embodiments in the present disclosure relate to [10] to [24] described below.

[10] A wiring board, comprising:
a substrate having a first surface and a second surface positioned opposite to the first surface; and
a mesh wiring layer disposed on the first surface of the substrate,
wherein the substrate has transparency,
wherein the mesh wiring layer includes a wire,
wherein the wire includes
   a black layer containing resin,
   a first metal layer disposed on the black layer, and
   a second metal layer disposed on the first metal layer, and
wherein the wire has a wire width less than or equal to 5.0 μm.

[11] The wiring board according to [10], further comprising:
a primer layer disposed between the substrate and the mesh wiring layer.

[12] The wiring board according to [10] or [11],
wherein the black layer has a thickness greater than or equal to 0.2 μm and less than or equal to 1.0 μm.

[13] The wiring board according to any one of [10] to [12],
wherein the black layer contains a dye or a pigment.

[14] The wiring board according to any one of [10] to [13],
wherein the first metal layer and the second metal layer have different crystal properties, and the second metal layer has a crystal property in which a diffraction angle 2θ of a (111) plane measured using Cu Kα radiation as an X-ray source is less than 43.4°.

[15] The wiring board according to any one of [10] to [14],
wherein the substrate has a dielectric loss tangent less than or equal to 0.002.

[16] The wiring board according to any one of [10] to [15],
wherein an increased rate of resistance of the mesh wiring layer is less than or equal to 20% when an operation including bending the wiring board 180° along a circumference of a cylinder with a diameter of 1 mm and then flattening the wiring board is performed 100 times.

[17] The wiring board according to any one of [10] to [16],
wherein the wiring board has a function of transmitting and receiving millimeter waves, and the mesh wiring layer serves as an array antenna.

[18] The wiring board according to any one of [10] to [17],
wherein at least one dummy wiring layer electrically separate from the mesh wiring layer is disposed around the mesh wiring layer.

[19] The wiring board according to [18],
wherein the at least one dummy wiring layer includes a plurality of dummy wiring layers, and the mesh wiring layer and the plurality of dummy wiring layers have aperture ratios that increase stepwise from the mesh wiring layer toward the plurality of dummy wiring layers, in a direction extending away from the mesh wiring layer.

[20] The wiring board according to any one of [10] to [19], further comprising:
a dark color layer covering the mesh wiring layer.

[21] The wiring board according to [20],
wherein the black layer has a lower 5° specular reflectance at a wavelength of 700 nm than the dark color layer does.

[22] The wiring board according to [20] or [21],
wherein the dark color layer and the black layer have different 5° specular reflectance spectra in a visible wavelength range.

[23] A wiring board, comprising:
a substrate having a first surface and a second surface positioned opposite to the first surface;
a primer layer disposed on the first surface of the substrate; and
a mesh wiring layer disposed on the primer layer,
wherein the substrate has transparency,
wherein the primer layer is a dark color layer,
wherein the mesh wiring layer includes a wire, and
wherein the wire includes
   a first metal layer disposed on the primer layer, and
   a second metal layer disposed on the first metal layer.

[24] An image display device, comprising:
the wiring board according to any one of [10] to [23]; and
a display device laminated on the wiring board.

### Advantageous Effects of Invention

According to embodiments of the present disclosure, a mesh wiring layer is less visually discernible, and adhesion between the substrate and the mesh wiring layer can be improved.

According to embodiments of the present disclosure, a mesh wiring layer is less visually discernible.

### BRIEF DESCRIPTION OF DRAWINGS

FIG. 1 is a plan view of an image display device according to a first embodiment.

FIG. 2 is a cross-sectional view of the image display device according to the first embodiment (a cross-sectional view taken along line II-II in FIG. 1).

FIG. 3 is a plan view of a wiring board according to the first embodiment.

FIG. 4 is an enlarged plan view of a mesh wiring layer of the wiring board according to the first embodiment.

FIG. 5 is a cross-sectional view of the wiring board according to the first embodiment (a cross-sectional view taken along line V-V in FIG. 4).

FIG. 6 is a cross-sectional view of the wiring board according to the first embodiment (a cross-sectional view taken along line VI-VI in FIG. 4).

FIG. 7A is a cross-sectional view of a method for manufacturing the wiring board according to the first embodiment.

FIG. 7B is a cross-sectional view of a method for manufacturing the wiring board according to the first embodiment.

FIG. 7C is a cross-sectional view of a method for manufacturing the wiring board according to the first embodiment.

FIG. 7D is a cross-sectional view of a method for manufacturing the wiring board according to the first embodiment.

FIG. 7E is a cross-sectional view of a method for manufacturing the wiring board according to the first embodiment.

FIG. 7F is a cross-sectional view of a method for manufacturing the wiring board according to the first embodiment.

FIG. 7G is a cross-sectional view of a method for manufacturing the wiring board according to the first embodiment.

FIG. 7H is a cross-sectional view of a method for manufacturing the wiring board according to the first embodiment.

FIG. 7I is a cross-sectional view of a method for manufacturing the wiring board according to the first embodiment.

FIG. 7J is a cross-sectional view of a method for manufacturing the wiring board according to the first embodiment.

FIG. 8 is a plan view of a wiring board according to a first modification example of the first embodiment.

FIG. 9 is an enlarged plan view of the wiring board according to the first modification example of the first embodiment.

FIG. 10 is a plan view of a wiring board according to a second modification example of the first embodiment.

FIG. 11 is an enlarged plan view of the wiring board according to the second modification example of the first embodiment.

FIG. 12 is a plan view of a wiring board according to a third modification example of the first embodiment.

FIG. 13 is a plan view of an image display device according to a second embodiment.

FIG. 14 is a cross-sectional view of an image display device according to the second embodiment (a cross-sectional view taken along line XIV-XIV in FIG. 13).

FIG. 15 is a plan view of a wiring board according to the second embodiment.

FIG. 16 is an enlarged plan view of a mesh wiring layer of the wiring board according to the second embodiment.

FIG. 17 is a cross-sectional view of the wiring board according to the second embodiment (a cross-sectional view taken along line XVII-XVII in FIG. 16).

FIG. 18 is a cross-sectional view of the wiring board according to the second embodiment (a cross-sectional view taken along line XVIII-XVIII in FIG. 16).

FIG. 19A is a cross-sectional view of a method for manufacturing the wiring board according to the second embodiment.

FIG. 19B is a cross-sectional view of a method for manufacturing the wiring board according to the second embodiment.

FIG. 19C is a cross-sectional view of a method for manufacturing the wiring board according to the second embodiment.

FIG. 19D is a cross-sectional view of a method for manufacturing the wiring board according to the second embodiment.

FIG. 19E is a cross-sectional view of a method for manufacturing the wiring board according to the second embodiment.

FIG. 19F is a cross-sectional view of a method for manufacturing the wiring board according to the second embodiment.

FIG. 19G is a cross-sectional view of a method for manufacturing the wiring board according to the second embodiment.

FIG. 19H is a cross-sectional view of a method for manufacturing the wiring board according to the second embodiment.

FIG. 19I is a cross-sectional view of a method for manufacturing the wiring board according to the second embodiment.

FIG. 20 is a cross-sectional view of a wiring board according to a first modification example of the second embodiment.

FIG. 21 is a cross-sectional view of the wiring board according to the first modification example of the second embodiment.

FIG. 22 is a cross-sectional view of a wiring board according to a second modification example of the second embodiment.

FIG. 23 is a cross-sectional view of the wiring board according to the second modification example of the second embodiment.

FIG. 24 is a cross-sectional view of a wiring board according to a comparative example.

FIG. 25 is a graph illustrating a reflectance spectrum.

FIG. 26 is a perspective view of a head mount display in which the wiring board according to the second modification example of the second embodiment is incorporated.

FIG. 27 is a diagram illustrating iridescent unevenness.

FIG. 28 is a cross-sectional view of a wiring board according to a third modification example of the second embodiment.

FIG. 29 is a cross-sectional view of the wiring board according to the third modification example of the second embodiment.

FIG. 30 is a plan view of a wiring board according to a fourth modification example of the second embodiment.

FIG. 31 is an enlarged plan view of the wiring board according to the fourth modification example of the second embodiment.

FIG. 32 is a plan view of a wiring board according to a fifth modification example of the second embodiment.

FIG. 33 is an enlarged plan view of the wiring board according to the fifth modification example of the second embodiment.

FIG. 34 is a plan view of a wiring board according to a sixth modification example of the second embodiment.

### DESCRIPTION OF EMBODIMENTS

### First Embodiment

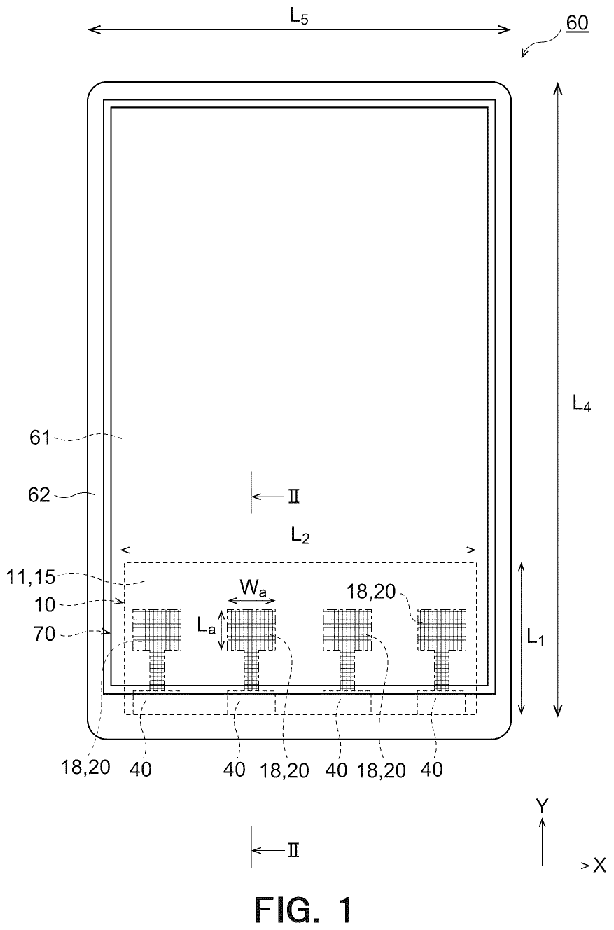

First, with reference to FIG. 1 to FIG. 7J, an embodiment is described. FIG. 1 to FIG. 7J are diagrams illustrating the present embodiment.

The drawings described below are schematic diagrams. The size or shape of each component is thus exaggerated as appropriate for ease of understanding. Within the scope not departing from the technical idea, each component may be changed as appropriate. Like reference signs denote like or corresponding components in the drawings described below, and some components may not be described in detail. The numerical values such as dimensions and material names of components described herein are merely examples according to the embodiments, and are not intended to be limiting, and alternatives may be selected and used as appropriate. Herein, terms used to define shapes or geometrical conditions, such as parallel, orthogonal, or vertical, may be interpreted to include not only the strict definitions of these terms, but also substantially equivalent states.

In the embodiments described below, an “X direction” refers to a direction parallel to one side of an image display device. A “Y direction” refers to a direction orthogonal to the X direction and parallel to another side of the image display device. A “Z direction” refers to a direction orthogonal to both the X direction and the Y direction and parallel to a thickness direction of the image display device. A “surface” refers to a surface facing in the positive Z direction, and a light emerging surface of the image display device. A “rear surface” refers to a surface facing in the negative Z direction, and a surface opposite to the light emerging surface of the image display device. In an example described in the present embodiment, mesh wiring layers 20 are mesh wiring layers having a function of transmitting and receiving radio waves (a function as an antenna), but the mesh wiring layers 20 may not have a function of transmitting and receiving radio waves.

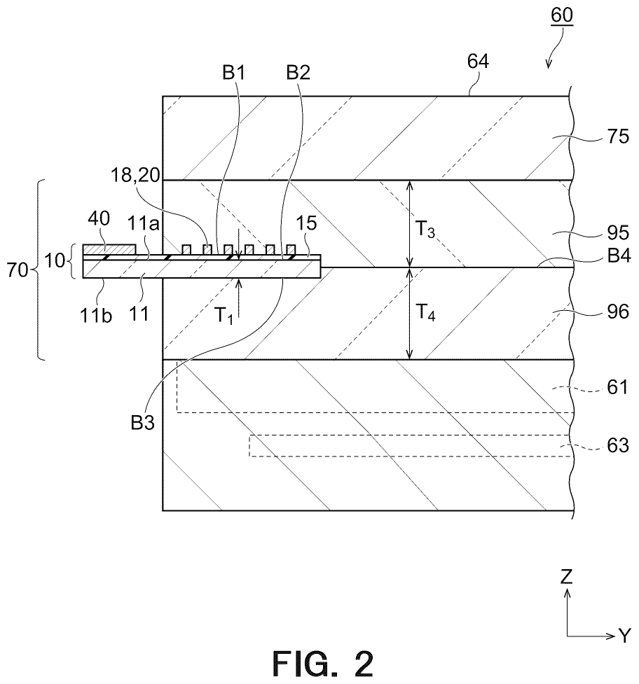

With reference to FIG. 1 and FIG. 2, a structure of an image display device according to the present embodiment is described.

As illustrated in FIG. 1 and FIG. 2, an image display device 60 according to the present embodiment includes a wiring board 10, and a display device 61 laminated on the wiring board 10. The wiring board 10 constitutes an image-display-device multilayer body 70 together with a first transparent adhesive layer 95 and a second transparent adhesive layer 96.

The wiring board 10 includes a substrate 11, a primer layer 15, mesh wiring layers 20 including first dark color layers 21c and 22c described below, second dark color layers 18, and feeding points 40. As illustrated in FIG. 2, the substrate 11 includes a first surface 11a and a second surface 11b positioned opposite to the first surface 11a. The primer layer 15 is disposed on the first surface 11a of the substrate 11. The mesh wiring layers 20 are disposed on the primer layer 15. The mesh wiring layers 20 are covered with the second dark color layers 18. The feeding points 40 are electrically connected to the mesh wiring layers 20. A communication module 63 is disposed in the negative Z direction from the display device 61. The image-display-device multilayer body 70, the display device 61, and the communication module 63 are accommodated in a housing 62.

The image display device 60 illustrated in FIG. 1 and FIG. 2 can transmit or receive radio waves of a predetermined frequency with the communication module 63 to perform communications. The communication module 63 may include any of antennas including a millimeter wave antenna, a telephone antenna, a Wi-Fi antenna, a 3G antenna, a 4G antenna, a 5G antenna, an LTE antenna, a Bluetooth (registered trademark) antenna, and an NFC antenna. Examples of the image display device 60 with this structure include a mobile terminal device such as a smartphone or a tablet. The frequency band for millimeter waves is greater than or equal to 30 GHz and lower than or equal to 100 GHz. The frequency band for 5G in Frequency Range 1 (Fr1) is greater than or equal to 450 MHz and lower than or equal to 6000 MHz, and the frequency band for 5G in Frequency Range 2 (Fr2) is greater than or equal to 24.25 GHz and lower than or equal to 52.6 GHz.

As illustrated in FIG. 2, the image display device 60 has a light emerging surface 64. The image display device 60 includes the wiring board 10 positioned closer to the light emerging surface 64 (in the positive Z direction) with respect to the display device 61, and the communication module 63 positioned away from the light emerging surface 64 (in the negative Z direction) with respect to the display device 61.

The display device 61 is formed from, for example, an organic electroluminescence (EL) display device. The display device 61 may include, for example, a metal layer, a support substrate, a resin substrate, a thin film transistor (TFT), and an organic EL layer, not illustrated. A touch sensor not illustrated may be disposed on the display device 61. The wiring board 10 is disposed on the display device 61 with the second transparent adhesive layer 96 interposed therebetween. The display device 61 is not limited to a display device formed from an organic EL display device. For example, the display device 61 may be another display device having a function of emitting light, for example, a micro-light-emitting-diode (LED) display device including micro-LED devices. Alternatively, the display device 61 may be a liquid-crystal display device including liquid crystals.

A cover glass 75 is disposed on the wiring board 10 with the first transparent adhesive layer 95 interposed therebetween. Between the first transparent adhesive layer 95 and the cover glass 75, a decorating film and a polarizing plate not illustrated may be disposed.

The first transparent adhesive layer 95 is an adhesive layer that directly or indirectly adheres the wiring board 10 to the cover glass 75. The first transparent adhesive layer 95 is positioned closer to the first surface 11a of the substrate 11. The first transparent adhesive layer 95 has optical transparency, and may be an optical clear adhesive (OCA) layer. The OCA layer is fabricated, for example, in the manner below. First, a curable adhesive-layer-forming liquid composite containing a polymerization compound is applied to a release film formed from, for example, polyethylene terephthalate (PET). The resultant is then left to cure using, for example, ultraviolet rays (UV) to obtain an OCA sheet. After the OCA sheet is stuck to a target object, the release film is removed to obtain the OCA layer. The first transparent adhesive layer 95 may be formed from, for example, acrylic resin, silicone resin, or polyurethane resin. Particularly, the first transparent adhesive layer 95 may contain acrylic resin. In this case, the second transparent adhesive layer 96 may contain acrylic resin. This structure substantially eliminates the difference in refractive index between the first transparent adhesive layer 95 and the second transparent adhesive layer 96, and can more reliably reduce reflection of visible light at an interface B4 between the first transparent adhesive layer 95 and the second transparent adhesive layer 96.

The first transparent adhesive layer 95 may have a visible light transmittance greater than or equal to 85%, or greater than or equal to 90%. Although the upper limit of the visible light transmittance of the first transparent adhesive layer 95 is not particularly determined, the upper limit may be, for example, lower than or equal to 100%. The first transparent adhesive layer 95 having a visible light transmittance within the above range can enhance transparency of the image-display-device multilayer body 70, and can make the display device 61 in the image display device 60 more easily visually discernible. Visible light refers to light with a wavelength greater than or equal to 400 nm and less than or equal to 700 nm. Having a visible light transmittance greater than or equal to 85% refers to that the transmittance is greater than or equal to 85% in the entire wavelength range greater than or equal to 400 nm and less than or equal to 700 nm when absorbance of a target component (for example, the first transparent adhesive layer 95) is measured. The absorbance may be measured with a spectrophotometer (spectroscope V-670 from JASCO Corporation).

As described above, the wiring board 10 is disposed closer to the light emerging surface 64 with respect to the display device 61. In this case, the wiring board 10 is positioned between the first transparent adhesive layer 95 and the second transparent adhesive layer 96. More specifically, a partial area of the substrate 11 in the wiring board 10 is disposed in the partial area between the first transparent adhesive layer 95 and the second transparent adhesive layer 96. In this case, the first transparent adhesive layer 95, the second transparent adhesive layer 96, the display device 61, and the cover glass 75 each have a larger area than the substrate 11 in the wiring board 10. Disposing the substrate 11 in the wiring board 10 in the partial area instead of the entire area of the image display device 60 in a plan view in this manner can reduce the entire thickness of the image display device 60.

As described above, the wiring board 10 includes the substrate 11 having transparency, the primer layer 15 disposed on the first surface 11a of the substrate 11, the mesh wiring layers 20 disposed on the primer layer 15, and the second dark color layers 18 covering the mesh wiring layers 20. The feeding points 40 are electrically connected to the mesh wiring layers 20. The feeding points 40 are electrically connected to the communication module 63 through feeders not illustrated. A part of the wiring board 10 protrudes outward (in the negative Y direction) between the first transparent adhesive layer 95 and the second transparent adhesive layer 96 without being disposed between the first transparent adhesive layer 95 and the second transparent adhesive layer 96. More specifically, an area of the wiring board 10 on which the feeding points 40 are disposed protrudes outward. This structure facilitates electrical connection between the feeding points 40 and the communication module 63. The area of the wiring board 10 on which the mesh wiring layers 20 are disposed is positioned between the first transparent adhesive layer 95 and the second transparent adhesive layer 96. The wiring board 10 is described in detail later.

The second transparent adhesive layer 96 directly or indirectly adheres the display device 61 to the wiring board 10. The second transparent adhesive layer 96 is positioned closer to the second surface 11b of the substrate 11. As in the first transparent adhesive layer 95, the second transparent adhesive layer 96 has optical transparency, and may be an optical clear adhesive (OCA) layer. The second transparent adhesive layer 96 may be formed from, for example, acrylic resin, silicone resin, or polyurethane resin. Particularly, the second transparent adhesive layer 96 may contain acrylic resin. This structure substantially eliminates the difference in refractive index between the first transparent adhesive layer 95 and the second transparent adhesive layer 96, and can more reliably reduce reflection of visible light at the interface B4 between the first transparent adhesive layer 95 and the second transparent adhesive layer 96.

The second transparent adhesive layer 96 may have a transmittance of visible light (light with a wavelength greater than or equal to 400 nm and less than or equal to 700 nm) greater than or equal to 85%, or greater than or equal to 90%. Although the upper limit of the visible light transmittance of the second transparent adhesive layer 96 is not particularly determined, the upper limit may be, for example, lower than or equal to 100%. The second transparent adhesive layer 96 having a visible light transmittance within the above range can enhance transparency of the image-display-device multilayer body 70, and can make the display device 61 in the image display device 60 more easily visually discernible.

In the image-display-device multilayer body 70, the difference in refractive index between the primer layer 15 and the first transparent adhesive layer 95 may be less than or equal to 0.1, or less than or equal to 0.05. The difference in refractive index between the primer layer 15 and the substrate 11 may be less than or equal to 0.1, or less than or equal to 0.05. The refractive index refers to an absolute refractive index, and can be obtained based on the method A in JIS K-7142. For example, when the first transparent adhesive layer 95 is formed from acrylic resin (with a refractive index 1.49), the refractive index of the primer layer 15 is greater than or equal to 1.39 and less than or equal to 1.59. Examples of such a material include fluorocarbon polymers, silicone resin, polyolefin resin, polyester resin, acrylic resin, polycarbonate resin, polyimide resin, and cellulosic resin.

In this manner, when the difference in refractive index between the primer layer 15 and the first transparent adhesive layer 95 is reduced to less than or equal to 0.1, reflection of visible light at the interface B1 between the primer layer 15 and the first transparent adhesive layer 95 is reduced, and the substrate 11 on which the primer layer 15 is disposed is less visually discernible to the naked eye of an observer. In addition, when the difference in refractive index between the primer layer 15 and the substrate 11 is reduced to less than or equal to 0.1, reflection of visible light at the interface B2 between the primer layer 15 and the substrate 11 is reduced, and the substrate 11 is less visually discernible to the naked eye of an observer.

In the image-display-device multilayer body 70, the difference in refractive index between the substrate 11 and the first transparent adhesive layer 95 may be less than or equal to 0.1, or less than or equal to 0.05. The difference in refractive index between the second transparent adhesive layer 96 and the substrate 11 may be less than or equal to 0.1, or less than or equal to 0.05. In addition, the difference in refractive index between the first transparent adhesive layer 95 and the second transparent adhesive layer 96 may be less than or equal to 0.1, or less than or equal to 0.05. For example, when the first transparent adhesive layer 95 and the second transparent adhesive layer 96 are formed from acrylic resin (with a refractive index of 1.49), the refractive index of the substrate 11 is greater than or equal to 1.39 and less than or equal to 1.59. As described above, examples of such a material include fluorocarbon polymers, silicone resin, polyolefin resin, polyester resin, acrylic resin, polycarbonate resin, polyimide resin, and cellulosic resin.

When the difference in refractive index between the second transparent adhesive layer 96 and the substrate 11 is reduced to less than or equal to 0.1, reflection of visible light at an interface B3 between the second transparent adhesive layer 96 and the substrate 11 can be reduced, and the substrate 11 is less visually discernible to the naked eye of an observer. In addition, when the difference in refractive index between the first transparent adhesive layer 95 and the second transparent adhesive layer 96 is reduced to less than or equal to 0.1, reflection of visible light at an interface B4 between the first transparent adhesive layer 95 and the second transparent adhesive layer 96 can be reduced, and the first transparent adhesive layer 95 and the second transparent adhesive layer 96 are less visually discernible to the naked eye of an observer.

Particularly, the first transparent adhesive layer 95 and the second transparent adhesive layer 96 may be formed from the same material. Thus, the difference in refractive index between the first transparent adhesive layer 95 and the second transparent adhesive layer 96 can be further reduced, and reflection of the visible light at the interface B4 between the first transparent adhesive layer 95 and the second transparent adhesive layer 96 can be reduced.

In FIG. 2, at least one of a thickness T₃ of the first transparent adhesive layer 95 and a thickness T₄ of the second transparent adhesive layer 96 may be greater than or equal to 1.5 times, greater than or equal to 2 times, or greater than or equal to 2.5 times a thickness T₁ of the substrate 11. When the thickness T₃ of the first transparent adhesive layer 95 or the thickness T₄ of the second transparent adhesive layer 96 is fully thicker than the thickness T₁ of the substrate 11, the first transparent adhesive layer 95 or the second transparent adhesive layer 96 deforms in the thickness direction to absorb the thickness of the substrate 11 in an area where the first transparent adhesive layer 95 or the second transparent adhesive layer 96 overlaps the substrate 11. This structure is less likely to allow the first transparent adhesive layer 95 or the second transparent adhesive layer 96 to have a level difference at the periphery of the substrate 11, and less likely to allow an observer to visually discern the presence of the substrate 11.

At least one of the thickness T₃ of the first transparent adhesive layer 95 and the thickness T₄ of the second transparent adhesive layer 96 may be less than or equal to 10 times or less than or equal to 5 times the thickness T₁ of the substrate 11. This structure can reduce the entire thickness of the image display device 60 without allowing the thickness T₃ of the first transparent adhesive layer 95 or the thickness T₄ of the second transparent adhesive layer 96 to be excessively large.

In FIG. 2, the thickness T₃ of the first transparent adhesive layer 95 and the thickness T₄ of the second transparent adhesive layer 96 may be the same. In this case, the thickness T₃ of the first transparent adhesive layer 95 and the thickness T₄ of the second transparent adhesive layer 96 may be greater than or equal to 1.5 times, or greater than or equal to 2.0 times the thickness T₁ of the substrate 11. More specifically, the sum (T₃+T₄) of the thickness T₃ of the first transparent adhesive layer 95 and the thickness T₄ of the second transparent adhesive layer 96 is greater than or equal to 3 times the thickness T₁ of the substrate 11. When the sum of the thicknesses T₃ and T₄ of the first transparent adhesive layer 95 and the second transparent adhesive layer 96 is sufficiently greater than the thickness T₁ of the substrate 11, the first transparent adhesive layer 95 and the second transparent adhesive layer 96 deform (shrink) in the thickness direction in the area where the first transparent adhesive layer 95 and the second transparent adhesive layer 96 overlap the substrate 11. Thus, the first transparent adhesive layer 95 and the second transparent adhesive layer 96 absorb the thickness of the substrate 11. This structure is less likely to allow the first transparent adhesive layer 95 or the second transparent adhesive layer 96 to have a level difference at the periphery of the substrate 11, and less likely to allow an observer to visually discern the presence of the substrate 11.

When the thickness T₃ of the first transparent adhesive layer 95 and the thickness T₄ of the second transparent adhesive layer 96 are the same, the thickness T₃ of the first transparent adhesive layer 95 and the thickness T₄ of the second transparent adhesive layer 96 may be less than or equal to 5 times or less than or equal to 3 times the thickness T₁ of the substrate 11. This structure can reduce the entire thickness of the image display device 60 without allowing the thicknesses T₃ and T₄ of the first transparent adhesive layer 95 and the second transparent adhesive layer 96 to be excessively large.

More specifically, the thickness T₁ of the substrate 11 may be, for example, greater than or equal to 2 μm, greater than or equal to 10 μm, or greater than or equal to 15 μm. When the thickness T₁ of the substrate 11 is greater than or equal to 2 μm, the wiring board 10 can maintain its strength, and, first direction wires 21 and second direction wires 22, described below, in the mesh wiring layers 20 can be less deformable. The thickness T₁ of the substrate 11 may be, for example, less than or equal to 200 μm, less than or equal to 50 μm, or less than or equal to 25 μm. The structure where the thickness T₁ of the substrate 11 is less than or equal to 200 μm is less likely to allow the first transparent adhesive layer 95 and the second transparent adhesive layer 96 to have a level difference at the periphery of the substrate 11, and less likely to allow an observer to visually discern the presence of the substrate 11. In addition, the structure where the thickness T₁ of the substrate 11 is less than or equal to 50 μm is further less likely to allow the first transparent adhesive layer 95 and the second transparent adhesive layer 96 to have a level difference at the periphery of the substrate 11, and further less likely to allow an observer to visually discern the presence of the substrate 11.

The thickness T₃ of the first transparent adhesive layer 95 may be, for example, greater than or equal to 15 μm or greater than or equal to 20 μm. The thickness T₃ of the first transparent adhesive layer 95 may be, for example, less than or equal to 500 μm, less than or equal to 300 μm, or less than or equal to 250 μm. The thickness T₄ of the second transparent adhesive layer 96 may be, for example, greater than or equal to 15 μm, or greater than or equal to 20 μm. The thickness T₄ of the second transparent adhesive layer 96 may be, for example, less than or equal to 500 μm, less than or equal to 300 μm, or less than or equal to 250 μm.

With reference to FIG. 2 again, the cover glass 75 is disposed on the first transparent adhesive layer 95. The cover glass 75 is a glass-made member that transmits light. The cover glass 75 is a plate, and may be rectangular in a plan view. The cover glass 75 may have a thickness of, for example, greater than or equal to 200 μm and less than or equal to 1000 μm, or greater than or equal to 300 μm and less than or equal to 700 μm. The dimension of the cover glass 75 in the longitudinal direction (the Y direction) may be, for example, greater than or equal to 20 mm and less than or equal to 500 mm, or greater than or equal to 100 mm and less than or equal to 200 mm. The dimension of the cover glass 75 in the lateral direction (the X direction) may be, for example, greater than or equal to 20 mm and less than or equal to 500 mm, or greater than or equal to 50 mm and less than or equal to 100 mm.

As illustrated in FIG. 1, the entire image display device 60 is substantially rectangular in a plan view, and has its longitudinal direction parallel to the Y direction, and its lateral direction parallel to the X direction. A length L₄ of the image display device 60 in the longitudinal direction (the Y direction) may be, for example, greater than or equal to 20 mm and less than or equal to 500 mm, or greater than or equal to 100 mm and less than or equal to 200 mm. A length L₅ of the image display device 60 in the lateral direction (the X direction) may be, for example, greater than or equal to 20 mm and less than or equal to 500 mm, or greater than or equal to 50 mm and less than or equal to 100 mm. The image display device 60 may have a rectangular shape with rounded corners in a plan view.

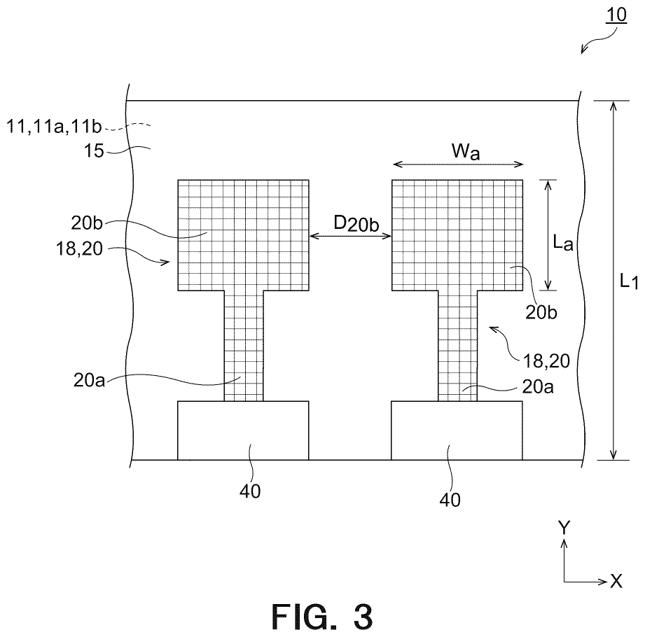

With reference now to FIG. 3 to FIG. 6, the structure of the wiring board is described. FIG. 3 to FIG. 6 are diagrams of the wiring board according to the present embodiment.

The wiring board 10 illustrated in FIG. 3 is a substrate included in the image display device 60 (refer to FIG. 1 and FIG. 2). The wiring board 10 may be disposed closer to the light emerging surface 64 with respect to the display device 61, and between the first transparent adhesive layer 95 and the second transparent adhesive layer 96. As described above, the wiring board 10 includes the substrate 11 having transparency, the primer layer 15 disposed on the substrate 11, the mesh wiring layers 20 disposed on the primer layer 15, and the second dark color layers 18 covering the mesh wiring layers 20. The mesh wiring layers 20 are electrically connected to the feeding points 40.

The substrate 11 has a substantially rectangular shape in a plan view. In the illustrated example, the substrate 11 has its longitudinal direction parallel to the X direction, and its lateral direction parallel to the Y direction. The substrate 11 has transparency and a substantially flat plate shape. The substrate 11 has a substantially uniform thickness. A length L₁ of the substrate 11 in the first direction (the Y direction) is selectable within the range of, for example, greater than or equal to 3 mm and less than or equal to 300 mm. A length L₂ (refer to FIG. 1) of the substrate 11 in the second direction (the X direction) is selectable within the range of, for example, greater than or equal to 3 mm and less than or equal to 300 mm. The substrate 11 may have a rectangular shape with rounded corners in a plan view.

The substrate 11 may be formed from any material that has transparency in a visible light area, and electrical insulating properties. For example, the substrate 11 may be formed from an organic insulation material such as polyester resin, acrylic resin, polycarbonate resin, polyimide resin, polyolefin resin, cellulosic resin, or fluorocarbon polymers. Polyester resin may be, for example, polyethylene terephthalate. Acrylic resin may be, for example, polymethyl methacrylate. Polyolefin resin may be, for example, cycloolefin polymers. Cellulosic resin may be triacetyl cellulose. Fluorocarbon polymers may be polytetrafluoroethylene (PTFE) or perfluoroalkoxy alkanes (PFA). For example, the substrate 11 may be formed from an organic insulation material such as cycloolefin polymers (for example, ZF-16 from Zeon Corporation) or polynorbornene polymers (from Sumitomo Bakelite Co., Ltd.). Alternatively, the substrate 11 may be formed from another material selected as appropriate for the purpose of use, such as glass or ceramics. Although the substrate 11 formed from a single layer is illustrated as an example, the substrate 11 may have a structure including multiple substrates or layers laminated one on another. The substrate 11 may be a film member or a plate member.

The substrate 11 may have a dielectric loss tangent less than or equal to 0.002, or less than or equal to 0.001. Although the lower limit of the dielectric loss tangent of the substrate 11 is not particularly limited, the lower limit of the dielectric loss tangent may be set slightly above zero. The substrate 11 with a dielectric loss tangent within the above range can reduce gain loss (sensitivity degradation) associated with electromagnetic wave transmission and reception particularly when the mesh wiring layers 20 transmit or receive high-frequency electromagnetic waves (for example, millimeter waves).

Although not limited to a particular value, the relative dielectric constant of the substrate 11 may be greater than or equal to 2 and less than or equal to 10. When the substrate 11 has a relative dielectric constant greater than or equal to 2, the material of the substrate 11 is selectable from among many alternatives. When the substrate 11 has a relative dielectric constant less than or equal to 10, gain loss associated with electromagnetic wave transmission and reception can be reduced. More specifically, when the substrate 11 has a larger relative dielectric constant, the effect of the thickness of the substrate 11 on propagation of electromagnetic waves increases. When propagation of the electromagnetic waves is adversely affected, the dielectric loss tangent of the substrate 11 may be increased, and gain loss associated with electromagnetic wave transmission and reception may be increased. In contrast, when the substrate 11 has a relative dielectric constant less than or equal to 10, the effect of the thickness of the substrate 11 on propagation of electromagnetic waves can be reduced. Thus, gain loss associated with electromagnetic wave transmission and reception can be reduced. Particularly, when the mesh wiring layers 20 transmit or receive high-frequency electromagnetic waves (for example, millimeter waves), gain loss associated with electromagnetic wave transmission and reception can be reduced.

The dielectric loss tangent and the relative dielectric constant of the substrate 11 may be measured in accordance with IEC 62562. More specifically, first, a portion of the substrate 11 on which the mesh wiring layers 20 are not formed is cut out to prepare a test piece. The test piece has a width greater than or equal to 10 mm and less than or equal to 20 mm and a length greater than or equal to 50 mm and less than or equal to 100 mm. Subsequently, the dielectric loss tangent or the relative dielectric constant is measured in accordance with IEC 62562.

In the present embodiment, the substrate 11 has transparency. Herein, “having transparency” refers to visible light (light with a wavelength greater than or equal to 400 nm and less than or equal to 700 nm) having a transmittance greater than or equal to 85%. The substrate 11 may have a visible light transmittance greater than or equal to 85% or greater than or equal to 90%. Although the upper limit of the visible light transmittance of the substrate 11 is not particularly determined, the upper limit may be, for example, lower than or equal to 100%. The substrate 11 having a visible light transmittance within the above range can enhance transparency of the wiring board 10, and can make the display device 61 in the image display device 60 more easily visually discernible.

The primer layer 15 is described now. The primer layer 15 improves adhesion between the mesh wiring layers 20 and the substrate 11. In the present embodiment, the primer layer 15 is disposed on substantially the entire first surface 11a of the substrate 11. This structure eliminates patterning of the primer layer 15. Thus, the number of processes can be reduced. The primer layer 15 may be simply disposed in an area of the first surface 11a of the substrate 11 on which the mesh wiring layers 20 are disposed.

The primer layer 15 contains a macromolecular material. Thus, the primer layer 15 can effectively improve adhesion between the mesh wiring layers 20 and the substrate 11. As an example material of the primer layer 15, a colorless, transparent macromolecular material may be used.

The primer layer 15 may contain acrylic resin or polyester resin. The primer layer 15 can thus effectively improve adhesion between the mesh wiring layers 20 and the substrate 11. When the primer layer 15 contains acrylic resin, examples of acrylic resins include polymers composed of monomer components such as acrylic acid, methacrylic acid, and their derivatives. As an example of acrylic resin, a polymer obtained by copolymerizing acrylic acid, methyl acrylate, ethyl acrylate, propyl acrylate, butyl acrylate, methacrylic acid, ethyl methacrylate, propyl methacrylate, butyl methacrylate, 2-ethylhexyl acrylate, acrylamide, acrylonitrile, or hydroxyl acrylate as a main component with monomers copolymerizable therewith (such as styrene, divinylbenzene, or acrylonitrile) may be used. Instead of the above monomers, for example, a dimer having two acryloyl or methacryloyl groups per molecule, or a multifunctional urethane acrylate may be added to resin serving as a main component, or an organic molecule having two or more epoxy groups per molecule may be added to resin serving as a main component. When acrylic resin is cross-linked to cure resin, the primer layer 15 can be formed. The cured primer layer has high adhesion. The cured primer layer may also have high water resistance, high acid resistance, high alkali resistance, or high solvent resistance, or a combination of these. Thus, the cured primer layer can reduce degradation of the adhesion between the mesh wiring layers 20 and the substrate 11 during wiring formation or over time.

When the primer layer 15 contains polyester resin, the primer layer 15 is formed by being cured by, for example, cross-linking polyester resin containing a hydroxyl group with a curing agent that reacts with a hydroxyl group. An example of polyester resin containing a hydroxyl group is polyester polyol, and examples of a curing agent include polyisocyanate and/or polyisocyanate prepolymer. The primer layer 15 formed by curing polyester polyol and polyisocyanate and/or polyisocyanate prepolymer has high adhesion. The cured primer layer may also have high water resistance, high acid resistance, high alkali resistance, or high solvent resistance, or a combination of these. Thus, the cured primer layer can reduce degradation of the adhesion between the mesh wiring layers 20 and the substrate 11 over time. The primer layer 15 formed by curing polyester polyol and polyisocyanate and/or polyisocyanate prepolymer also has high thermal resistance. Thus, the primer layer 15 is less likely to be affected by heat generated during processing such as deposition processes performed after the primer layer 15 is formed, and the primer layer 15 is thus less likely to be, for example, whitened or cracked by heat.

Examples of polyisocyanate and/or polyisocyanate prepolymers include isophorone diisocyanate (IPDI), xylylene diisocyanate (XDI), and hexamethylene diisocyanate (HDI)-based polyisocyanate and/or IPDI, XDI, and HDI-based polyisocyanate prepolymers. Use of any of these materials reduces yellowing of the primer layer 15. The term IPDI-based refers to isophorone diisocyanate and its modified forms, the term XDI-based refers to xylylene diisocyanate and its modified forms, and the term HDI-based refers to hexamethylene diisocyanate and its modified forms. Examples of the modified forms include the trimethylolpropane (TMP) adduct, isocyanurate, biuret, and allophanate.

The macromolecular material of the primer layer 15 may be cured by cross-linking, by irradiating the macromolecular material with visible light, ultraviolet rays, X rays, electron beams, x-rays, β-rays, or γ-rays. The primer layer 15 thus can improve scratch resistance and thermal resistance.

The primer layer 15 may have a transmittance of visible light (light with a wavelength greater than or equal to 400 nm and less than or equal to 700 nm) greater than or equal to 85%, or greater than or equal to 90%. Although the upper limit of the visible light transmittance of the primer layer 15 is not particularly determined, the upper limit may be, for example, lower than or equal to 100%. The primer layer 15 having a visible light transmittance within the above range can enhance transparency of the wiring board 10, and can make the display device 61 in the image display device 60 more easily visually discernible.

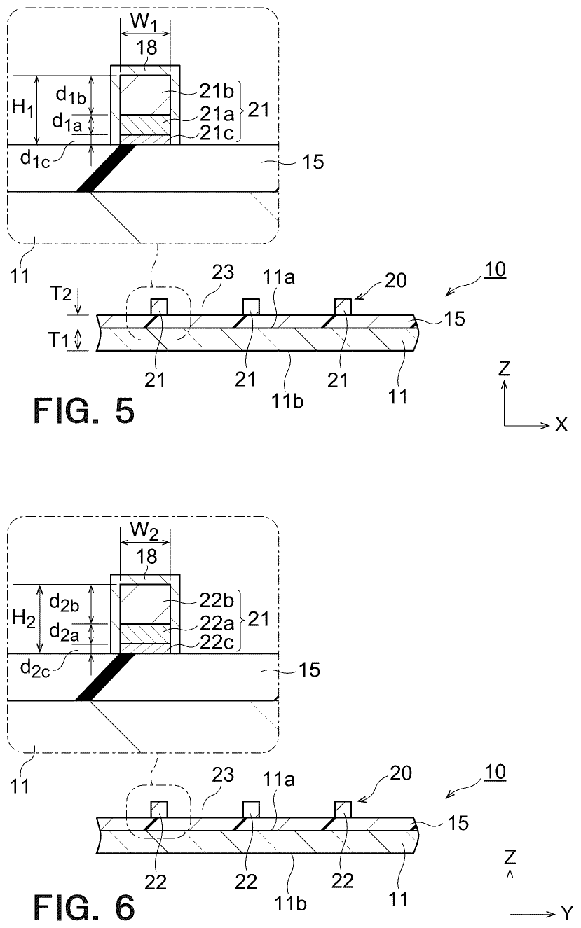

The primer layer 15 may have a thickness T₂ (or a dimension in the Z direction, refer to FIG. 5) greater than or equal to 0.05 μm and less than or equal to 0.5 μm. When the thickness T₂ of the primer layer 15 is greater than or equal to 0.05 μm, adhesion between the mesh wiring layers 20 and the substrate 11 can be effectively improved. When the thickness T₂ of the primer layer 15 is less than or equal to 0.5 μm, the wiring board 10 can maintain transparency.

In the present embodiment, the mesh wiring layers 20 serve as transmitter-receivers of electromagnetic waves. In this case, the mesh wiring layers 20 are formed from antenna patterns having a function as an antenna. The mesh wiring layers 20 may instead be formed as array antennas. When the mesh wiring layers 20 are formed as array antennas, the mesh wiring layers 20 have an enhanced performance of a millimeter-wave antenna that transmits or receives highly directional millimeter waves. An array antenna is an antenna including multiple antenna elements (radiating elements) arranged regularly, and that can independently control the amplitude and phase of excitation for the multiple elements.

As illustrated in FIG. 3, the multiple mesh wiring layers 20 are disposed on the substrate 11. Four or more mesh wiring layers 20 may be provided. In the illustrated example, four mesh wiring layers 20 are disposed on the substrate 11 (refer to FIG. 1). As illustrated in FIG. 3, the mesh wiring layers 20 may be simply located at a partial area on the substrate 11, instead of being located throughout the entire surface of the substrate 11. The mesh wiring layers 20 may have the same shape. In this case, in each of the mesh wiring layers 20, an error of a length (distance in the Y direction) Lₐ of a distal end portion 20b, described later, and an error of a width (distance in the X direction) Wₐ of the distal end portion 20b may be within a range of 10%. The mesh wiring layers 20 can thus effectively enhance the performance of a millimeter-wave antenna.

The mesh wiring layers 20 each include a proximal end portion (transmission portion) 20a located closer to the corresponding feeding point 40, and a distal end portion (transmitter-receiver) 20b connected to the proximal end portion 20a. The proximal end portion 20a is connected to the feeding point 40. In this case, the proximal end portion (transmission portion) 20a may be a microstrip line or a coplanar line. The proximal end portion 20a and the distal end portion 20b are substantially rectangular in a plan view. In this case, the width (distance in the X direction) of the distal end portion 20b is greater than the width (distance in the X direction) of the proximal end portion 20a.

The distal end portion 20b of each mesh wiring layer 20 corresponds to a predetermined frequency band. More specifically, the distal end portion 20b has the length (distance in the Y direction) Lₐ corresponding to a specific frequency band. The length Lₐ of the distal end portion 20b is longer as the corresponding frequency band is lower. Instead of the millimeter-wave antenna, each mesh wiring layer 20 may correspond to, for example, any of a telephone antenna, a Wi-Fi antenna, a 3G antenna, a 4G antenna, a 5G antenna, an LTE antenna, a Bluetooth (registered trademark) antenna, and an NFC antenna. The multiple distal end portions 20b may have different lengths and may correspond to different frequency bands. Alternatively, when the wiring board 10 does not have a radio-wave transmission reception function, each of the mesh wiring layers 20 may have, for example, a hovering function, a fingerprint authentication function, a heater function, or a noise-cut function (shield function). The hovering function is a function that allows a user to control a display without directly touching the display.

In the illustrated example, the distal end portion 20b has its longitudinal direction parallel to the X direction, and its lateral direction parallel to the Y direction. The distal end portion 20b may have its longitudinal direction parallel to the Y direction, and its lateral direction parallel to the X direction. The length Lₐ of the distal end portion 20b in the Y direction is selectable within a range of, for example, greater than or equal to 1 mm and less than or equal to 100 mm. The width Wₐ of the distal end portion 20b in the X direction is selectable within a range of, for example, greater than or equal to 1 mm and less than or equal to 100 mm. Particularly, when each mesh wiring layer 20 is a millimeter-wave antenna, the length Lₐ of the distal end portion 20b may be greater than or equal to 1 mm, or greater than or equal to 1.5 mm. When each mesh wiring layer 20 is a millimeter-wave antenna, the length Lₐ of the distal end portion 20b may be less than or equal to 10 mm, or less than or equal to 5 mm.

The distance between the mesh wiring layers 20 may be set as appropriate in accordance with the corresponding frequencies, but may be greater than or equal to 1 mm and less than or equal to 30 mm. More specifically, a distance D_{20b} (refer to FIG. 3) between the distal end portions 20b may be greater than or equal to 1 mm and less than or equal to 30 mm. Setting an appropriate distance can improve intended antenna directivity and gain.

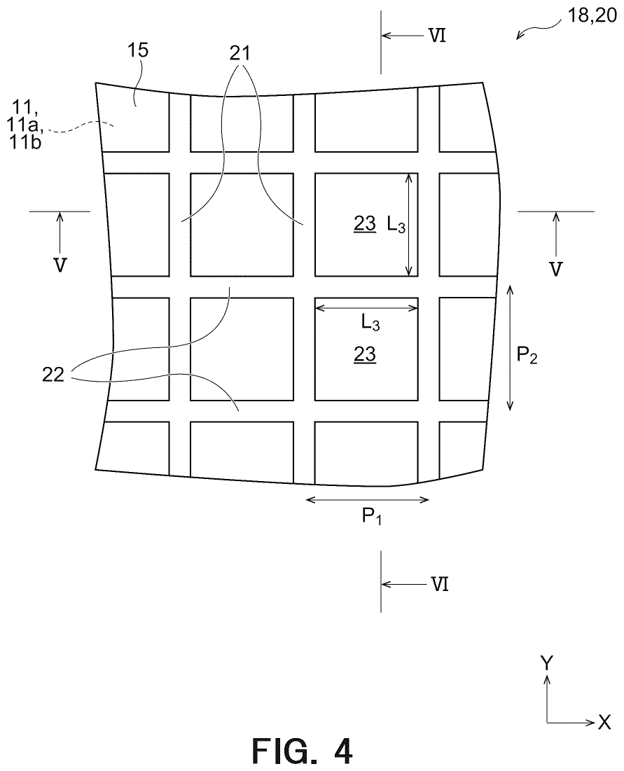

As illustrated in FIG. 4, each mesh wiring layer 20 has a pattern shape formed by arranging metal wires into a grid or mesh pattern. This pattern shape is repeatedly disposed in the X direction and the Y direction. More specifically, each mesh wiring layer 20 has a pattern shape including portions (first direction wires 21, described later) extending in a first direction (for example, the Y direction), and portions (second direction wires 22, described later) extending in a second direction (for example, the X direction).

As illustrated in FIG. 4, each mesh wiring layer 20 includes multiple wires. More specifically, each mesh wiring layer 20 includes multiple first direction wires 21 and multiple second direction wires 22 connecting the multiple first direction wires 21. The multiple first direction wires 21 and the multiple second direction wires 22 are integrated into a unit to collectively form a grid or mesh pattern. Each first direction wire 21 extends rectilinearly in the longitudinal direction (the Y direction) of the mesh wiring layer 20. Each second direction wire 22 extends rectilinearly in the width direction (the X direction) of the mesh wiring layer 20. The first direction wires 21 and the second direction wires 22 may extend in directions parallel to neither the X direction nor the Y direction.

Each mesh wiring layer 20 has multiple apertures 23 defined by the first direction wires 21 adjacent to each other and the second direction wires 22 adjacent to each other. The substrate 11 having transparency is exposed through the apertures 23. Thus, the entire wiring board 10 has enhanced transparency.

In a plan view, each aperture 23 has a substantially square shape. More specifically, the first direction wires 21 and the second direction wires 22 are evenly spaced. The multiple first direction wires 21 are evenly spaced at a pitch P₁ within a range of, for example, greater than or equal to 0.01 mm and less than or equal to 1 mm. The multiple second direction wires 22 are evenly spaced at a pitch P₂ within a range of, for example, greater than or equal to 0.01 mm and less than or equal to 1 mm. When the multiple first direction wires 21 are evenly spaced and the multiple second direction wires 22 are evenly spaced, the apertures 23 in each mesh wiring layer 20 have an even size, and thus the mesh wiring layers 20 are less visually discernible to the naked eye. The pitch P₁ of the first direction wires 21 is equal to the pitch P₂ of the second direction wires 22. The apertures 23 thus have a substantially square shape in a plan view, and the primer layer 15 having transparency and the substrate 11 are exposed through the apertures 23. Thus, increasing the area of each aperture 23 can enhance the transparency of the entire wiring board 10. One side of each aperture 23 has a length L₃ of, for example, within a range greater than or equal to 0.01 mm and less than or equal to 1 mm. Although the first direction wires 21 and the second direction wires 22 are perpendicular to each other, the first direction wires 21 and the second direction wires 22 may instead intersect each other at an acute angle or an obtuse angle. The apertures 23 may have the same shape and the same size throughout the entire surface, or may have different shapes or different sizes at different positions on the surface.

As illustrated in FIG. 5, each first direction wire 21 has a substantially rectangular or substantially square cross section taken perpendicular to the longitudinal direction (taken in the X direction). In this case, the first direction wire 21 has a cross section substantially uniform in the longitudinal direction (the Y direction) of the first direction wire 21. As illustrated in FIG. 6, each second direction wire 22 has a substantially rectangular or substantially square cross section taken perpendicular to the longitudinal direction (taken in the Y direction), and has substantially the same shape as the cross section of the first direction wire 21 (taken in the X direction). In this case, the second direction wire 22 has a cross section substantially uniform in the longitudinal direction (the X direction) of the second direction wire 22. The cross-sectional shape of the first direction wires 21 and the cross-sectional shape of the second direction wires 22 do not necessarily have to be substantially rectangular or substantially square. For example, the cross-sectional shape of the first direction wires 21 and the cross-sectional shape of the second direction wires 22 may be substantially trapezoidal with the side closer to the surface (located in the positive Z direction) smaller than the size closer to the rear surface (located in the negative Z direction), or may have curved side surfaces on both sides in the width direction.

In the present embodiment, a wire width W₁ (refer to FIG. 5) of each first direction wire 21 and a wire width W₂ (refer to FIG. 6) of each second direction wire 22 are not particularly limited, and may be selected as appropriate in accordance with the purpose of use. The wire width W₁ of each first direction wire 21 is a width (dimension in the X direction) in a cross section taken perpendicular to the longitudinal direction, and the wire width W₂ of each second direction wire 22 is a width (dimension in the Y direction) in a cross section taken perpendicular to the longitudinal direction. For example, the wire width W₁ of each first direction wire 21 may be selected within a range greater than or equal to 0.1 μm and less than or equal to 5.0 μm, or greater than or equal to 0.2 μm and less than or equal to 2.0 μm. The wire width W₂ of each second direction wire 22 may be selected within a range greater than or equal to 0.1 μm and less than or equal to 5.0 μm, or greater than or equal to 0.2 μm and less than or equal to 2.0 μm. When the wire width W₁ of each first direction wire 21 and the wire width W₂ of each second direction wire 22 are less than or equal to 5.0 μm, the mesh wiring layers 20 are less visually discernible to the naked eye.

A height H₁ (refer to FIG. 5) of the first direction wires 21 and a height H₂ (refer to FIG. 6) of the second direction wires 22 are not particularly limited, and may be selected as appropriate in accordance with the purpose of use. The height H₁ of the first direction wires 21 and the height H₂ of the second direction wires 22 are dimensions in the Z direction. The height H₁ of the first direction wires 21 and the height H₂ of the second direction wires 22 are selectable within a range of, for example, greater than or equal to 60 nm and less than or equal to 5.0 μm.

As illustrated in FIG. 5 and FIG. 6, the mesh wiring layers 20 include first dark color layers 21c and 22c disposed on the primer layer 15, first metal layers 21a and 22a disposed on the first dark color layers 21c and 22c, and second metal layers 21b and 22b disposed on the first metal layers 21a and 22a. More specifically, each first direction wire 21 includes the first dark color layer 21c disposed on the primer layer 15, the first metal layer 21a disposed on the first dark color layer 21c, and the second metal layer 21b disposed on the first metal layer 21a. Each second direction wire 22 includes the first dark color layer 22c disposed on the primer layer 15, the first metal layer 22a disposed on the first dark color layer 22c, and the second metal layer 22b disposed on the first metal layer 22a.

The first dark color layers 21c and 22c reduce reflection of visible light that is incident on each mesh wiring layer 20 from the substrate 11 to make the mesh wiring layer 20 less visually discernible to the naked eye.

The first dark color layers 21c and 22c may be layers with a dark color such as black. The first dark color layers 21c and 22c may be formed by subjecting a metal layer formed by, for example, sputtering or vapor deposition to darkening treatment (blackening treatment). In this case, the first dark color layers 21c and 22c may be layers formed from a metal oxide or a metal sulfide. The first dark color layers 21c and 22c may be layers containing palladium or tellurium. The first dark color layers 21c and 22c may be metal layers with a dark color disposed on the surface of the primer layer 15 by, for example, sputtering or vapor deposition. The first dark color layers 21c and 22c may be layers formed from copper, nickel, or chromium (hereafter also referred to as copper or the like). The first dark color layers 21c and 22c may be layers formed from, for example, an alloy of copper or the like, a nitride or an oxide of a single metal such as copper or the like, or a nitride or an oxide of an alloy of copper or the like.

The first dark color layers 21c and 22c have a surface roughness Sa (arithmetic mean height of the surface) greater than or equal to 5 nm and less than or equal to 200 nm. When the surface roughness Sa of the first dark color layers 21c and 22c is greater than or equal to 5 nm, reflection of visible light at the first dark color layers 21c and 22c can be reduced. Thus, the mesh wiring layers 20 are less visually discernible to the naked eye of an observer. When the surface roughness Sa of the first dark color layers 21c and 22c is less than or equal to 200 nm, the haze values of the first dark color layers 21c and 22c can be regulated without rising to an excessively high level. This structure less easily allows an observer to visually discern the presence of the first dark color layers 21c and 22c. The mesh wiring layers 20 are thus less visually discernible to the naked eye of the observer. To measure the surface roughness Sa of the first dark color layers 21c and 22c, the surface roughness Sa of the rear surfaces of the first dark color layers 21c and 22c are measured based on ISO 25178 using a laser microscope (VK-X1000 from Keyence Corporation). To measure the surface roughness Sa of the first dark color layers 21c and 22c, first, the wiring board 10 is set to the laser microscope to irradiate the wiring board 10 with laser beams from the second surface 11b of the substrate 11. The magnifying power of the objective lens is set to 50. In this case, the measurement area is approximately 270 μm×200 μm. The wiring board 10 is then irradiated with laser beams from the second surface 11b of the substrate 11. The surface roughness Sa of the first dark color layers 21c and 22c is thus measured. With this measurement method, the surface roughness Sa of the first dark color layers 21c and 22c can be measured even after the first metal layers 21a and 22a and the second metal layers 21b and 22b are laminated on the first dark color layers 21c and 22c.

Thicknesses d_{1c} and d_{2C} of the first dark color layers 21c and 22c may be greater than or equal to 0.1 μm and less than or equal to 5.0 μm, greater than or equal to 0.2 μm and less than or equal to 4.5 μm, or greater than or equal to 0.3 μm and less than or equal to 4.0 μm. When the thicknesses d_{1c} and d_{2c} of the first dark color layers 21c and 22c are greater than or equal to 0.1 μm, the adhesion between the primer layer 15 and the first dark color layers 21c and 22c, and the adhesion between the first dark color layers 21c and 22c and the first metal layers 21a and 22a can be improved. When the thicknesses d_{1c} and d_{2c} of the first dark color layers 21c and 22c are less than or equal to 5.0 μm, the haze values of the first dark color layers 21c and 22c can be regulated without rising to an excessively high level, and this structure less easily allows an observer to visually discern the presence of the first dark color layers 21c and 22c. The mesh wiring layers 20 are thus less visually discernible to the naked eye of the observer. When the thicknesses d_{1c} and d_{2c} of the first dark color layers 21c and 22c are less than or equal to 5.0 μm, the mesh wiring layers 20 can be formed in a shorter time.

The first metal layers 21a and 22a have a function of improving adhesion between the substrate 11 and the mesh wiring layers 20. The first metal layers 21a and 22a also function as seed layers when the second metal layers 21b and 22b are to be formed with electroplating. The first metal layers 21a and 22a may be formed by, for example, sputtering or vapor deposition. The first metal layers 21a and 22a may be formed by the same method as the method for forming the first dark color layers 21c and 22c.

Thicknesses d₁ₐ and d₂ₐ of the first metal layers 21a and 22a may be greater than or equal to 10 nm and less than or equal to 1000 nm, greater than or equal to 30 nm and less than or equal to 500 nm, or greater than or equal to 50 nm and less than or equal to 300 nm. When the thicknesses d₁ₐ and d₂ₐ of the first metal layers 21a and 22a are greater than or equal to 10 nm, the first metal layers 21a and 22a can effectively support the second metal layers 21b and 22b when the second metal layers 21b and 22b are formed on the first metal layers 21a and 22a. When the thicknesses d₁ₐ and d₂ₐ of the first metal layers 21a and 22a are less than or equal to 1000 nm, the mesh wiring layers 20 can be formed in a shorter time.

The second metal layers 21b and 22b have a function of increasing the height H₁ of the first direction wires 21 and the height H₂ of the second direction wires 22. Thus, the first direction wires 21 and the second direction wires 22 can reduce resistance. The second metal layers 21b and 22b may be formed by, for example, plating or electroplating.

Thicknesses d_{1b} and d_{2b} of the second metal layers 21b and 22b may be greater than or equal to 50 nm and less than or equal to 4990 nm, greater than or equal to 100 nm and less than or equal to 2000 nm, or greater than or equal to 200 nm and less than or equal to 1800 nm. When the thicknesses d_{1b} and d_{2b} of the second metal layers 21b and 22b are greater than or equal to 50 nm, the height H₁ of the first direction wires 21 and the height H₂ of the second direction wires 22 can be increased, and the resistance of the first direction wires 21 and the second direction wires 22 can be reduced. When the thicknesses d_{1b} and d_{2b} of the second metal layers 21b and 22b are less than or equal to 4990 nm, the mesh wiring layers 20 can be formed in a shorter time.

The first dark color layers 21c and 22c and the first metal layers 21a and 22a may have the same crystal property. In contrast, the first metal layers 21a and 22a and the second metal layers 21b and 22b may have different crystal properties. The first metal layers 21a and 22a and the second metal layers 21b and 22b may differ in at least one of crystal fraction, crystal structure, crystallite size, and crystal plane interval. For example, the first metal layers 21a and 22a may have a diffraction angle 2θ of the (111) plane measured using Cu Kα radiation as an X-ray source greater than the diffraction angle 2θ of the (111) plane of the second metal layers 21b and 22b. For example, the first metal layers 21a and 22a may have a crystal property in which the diffraction angle 2θ of the (111) plane measured using Cu Kα radiation as an X-ray source is less than or equal to 43.430°. Thus, the adhesion between the first dark color layers 21c and 22c and the first metal layers 21a and 22a can be improved. In this case, the above diffraction angle 2θ may be less than or equal to 43.420, or less than or equal to 43.410°. Although the lower limit of the above diffraction angle 2θ is not particularly limited, the lower limit of the diffraction angle 2θ may be set greater than or equal to 43.250°, greater than or equal to 43.300°, or greater than or equal to 43.350°. The diffraction angle can be measured using an X-ray diffractometer (Smart Lab, 9-kW type from Rigaku Corporation). The diffraction angle 2θ of the (111) plane of the first metal layers 21a and 22a and the diffraction angle 2θ of the (111) plane of the second metal layers 21b and 22b are measured at the feeding points 40. As described later, concurrently with the first metal layers 21a and 22a and the second metal layers 21b and 22b, the feeding points 40 are formed from parts of a second metal film 51 forming the first metal layers 21a and 22a and parts of a third metal film 52 forming the second metal layers 21b and 22b. Thus, the diffraction angle 2θ of the (111) plane of the first metal layers 21a and 22a and the diffraction angle 2θ of the (111) plane of the second metal layers 21b and 22b can be measured at the feeding points 40. In this case, for example, the diffraction angle 2θ of the (111) plane of the first metal layers 21a and 22a can be more accurately measured compared to the case where, for example, the diffraction angle 2θ of the (111) plane of the first metal layers 21a and 22a is measured in the mesh wiring layers 20 in which the wire widths W₁ and W₂ are relatively narrow. Measurement conditions are described below.

Measurement mode: 2θ/θ measurement (Out-of-Plane)

X-ray source: Cu-Kα, 45 kV, 50 mA

Optical system: focusing

Incident optical system 1: solar slit, 5 deg

Incident optical system 2: variable slit (IS), 1 deg

Longitudinal restriction slit: 10 mm

Receiving optical system 1: variable slit (RS1), 1 deg, receiving slit (RS2), 0.3 mm

Receiving optical system 2: PSA OPEN/solar slit, 5 deg

Detector: scintillation counter

Measurement range: 35 to 80 deg

Step size: 0.02 deg

Measurement speed: 2.0 deg/min

The second metal layers 21b and 22b may have a crystal property in which the diffraction angle 2θ of the (111) plane measured using Cu Kα radiation as an X-ray source is less than 43.4°. Thus, the second metal layers 21b and 22b have improved plasticity when formed by etching. The diffraction angle 2θ of the (111) plane of the second metal layers 21b and 22b may be less than or equal to 43.390°, less than or equal to 43.380°, or less than or equal to 43.370°.

The first direction wires 21 and the second direction wires 22 may be formed from any electroconductive metal material. More specifically, the first dark color layers 21c and 22c, the first metal layers 21a and 22a, and the second metal layers 21b and 22b may be formed from any electroconductive metal material. In the present embodiment, the first direction wires 21 and the second direction wires 22 are formed from copper, but this is not the only possible example. The first direction wires 21 and the second direction wires 22 may be formed from, for example, a metal material such as gold, silver, copper, platinum, tin, aluminum, iron, or nickel, or an alloy containing any of these metals. The material of the first metal layers 21a and 22a and the material of the second metal layers 21b and 22b may be the same. In this structure, adhesion between the first metal layers 21a and 22a and the second metal layers 21b and 22b can be improved.

An aperture ratio At of the entirety of each mesh wiring layer 20 may be, for example, within a range greater than or equal to 87% and less than 100%. When the aperture ratio At of the entirety of each mesh wiring layer 20 is within this range, the wiring board 10 can maintain its electroconductivity and transparency. The aperture ratio At of the entirety of each mesh wiring layer 20 may be greater than or equal to 95% and less than 100%. Thus, the wiring board 10 has improved transparency while maintaining its electroconductivity. The aperture ratio refers to a ratio (%) of the area of an aperture region to the unit area of a predetermined region (for example, the entire area of each mesh wiring layer 20). The aperture region refers to a region not including metal portions such as the first direction wires 21 and the second direction wires 22 and through which the substrate 11 is exposed.

When the wiring board 10 is subjected to an elasticity test, the resistance of the mesh wiring layers 20 may have an increased rate less than or equal to 20%, or less than or equal to 10%. The elasticity test includes an operation performed 100 times by a cylindrical mandrel bending tester, the operation including bending the wiring board 10 180° along the circumference of the cylinder with a diameter of 1 mm and then flattening the wiring board 10.

More specifically, the test is performed in the manner below. First, the electric resistance between both ends of one mesh wiring layer 20 in the longitudinal direction is measured. This resistance is denoted by R₀ (Ω). The wiring board 10 is then wound around the cylinder of the cylindrical mandrel bending tester, while both ends of the wiring board 10 in the longitudinal direction are facing in opposite directions, 180° from each other. Thereafter, the wiring board 10 is unwound from the cylinder, and flattened. This operation is repeated 100 times. Thereafter, the electric resistance between both ends of the mesh wiring layer 20 in the longitudinal direction is measured again. This resistance is denoted by R₁ (Ω). The value obtained by ((R₁−R₀)/R₀)×100(%) is referred to as an increased rate of resistance. When the increased rate of resistance is less than or equal to 20%, the wiring board 10 has improved durability when used in a curved or bent form.

The second dark color layers 18 are then described. As illustrated in FIG. 5 and FIG. 6, the second dark color layers (blackening layers) 18 are formed on the mesh wiring layers 20 of the wiring board 10. The second dark color layers 18 reduce reflection of visible light at the mesh wiring layers 20 to make the mesh wiring layers 20 less visually discernible to the naked eye. The second dark color layers 18 cover the entirety of the mesh wiring layers 20. The second dark color layers 18 may further cover the entirety of the feeding points 40.

The second dark color layers 18 may be layers with a dark color such as black. Alternatively, the second dark color layers 18 may be layers with a rough surface.

The second dark color layers 18 have a surface roughness Sa greater than or equal to 5 nm and less than or equal to 100 nm. When the surface roughness Sa of the second dark color layers 18 is greater than or equal to 5 nm, reflection of visible light at the surface of the second dark color layers 18 can be reduced. Each mesh wiring layer 20 covered with the corresponding second dark color layer 18 is less visually discernible to the naked eye of an observer. When the surface roughness Sa of the second dark color layers 18 is less than or equal to 100 nm, the haze values of the second dark color layers 18 can be regulated without rising to an excessively high level. This structure thus less easily allows the observer to visually discern the presence of the second dark color layers 18. The mesh wiring layers 20 covered with the second dark color layers 18 are thus less visually discernible to the naked eye of the observer. In this case, the surface roughness Sa is obtained based on ISO 25178 using a laser microscope (VK-X1000 from Keyence Corporation).

The second dark color layers 18 may be formed from parts of the mesh wiring layers 20 or the feeding points 40 by, for example, subjecting parts of a metal material forming the mesh wiring layers 20 or the feeding points 40 to darkening treatment (blackening treatment). In this case, the second dark color layers 18 may be layers formed from a metal oxide or a metal sulfide. Alternatively, each second dark color layer 18 may be formed on the surface of the corresponding mesh wiring layer 20 or the corresponding feeding point 40 as a coating of a dark color material or a plating layer formed from, for example, nickel or chromium. Alternatively, each second dark color layer 18 may be formed by roughening the surface of the corresponding mesh wiring layer 20 or the corresponding feeding point 40.

Although not illustrated, a protective layer may be disposed on the primer layer 15 to cover the mesh wiring layers 20 and the second dark color layers 18. The protective layer protects the mesh wiring layers 20, and is disposed to cover at least the mesh wiring layers 20 on the substrate 11. Examples of the material of the protective layer include acrylic resin such as polymethyl methacrylate or polyethyl methacrylate, its modified resin, and its copolymer, polyvinyl resin such as polyester, polyvinyl alcohol, polyvinyl acetate, polyvinyl acetal, or polyvinyl butyral, and its copolymer, or a colorless, transparent insulating resin such as polyurethane, epoxy resin, polyamide, or chlorinated polyolefin.

With reference back to FIG. 3, the feeding points 40 are electrically connected to the mesh wiring layers 20. The feeding points 40 are formed from substantially rectangular electroconductive thin plate members. The longitudinal direction of the feeding points 40 is parallel to the X direction, and the lateral direction of the feeding points 40 is parallel to the Y direction. The feeding points 40 are located at an end of the substrate 11 in the longitudinal direction (end in the negative Y direction). The feeding points 40 may be formed from, for example, a metal material such as gold, silver, copper, platinum, tin, aluminum, iron, or nickel, or an alloy containing any of these metals. When the wiring board 10 is incorporated in the image display device 60 (refer to FIG. 1 and FIG. 2), the feeding points 40 are electrically connected to the communication module 63 in the image display device 60 with feeders not illustrated. Although the feeding points 40 are disposed on the first surface 11a of the substrate 11, parts or the entireties of the feeding points 40 may be located outward from the peripheral edge of the substrate 11. Alternatively, the feeding points 40 may be formed flexibly to be extended to the side surfaces or the rear surface of the image display device 60. In this case, the feeding points 40 may be electrically connected to the communication module 63 on the side surfaces or the rear surface of the image display device 60.

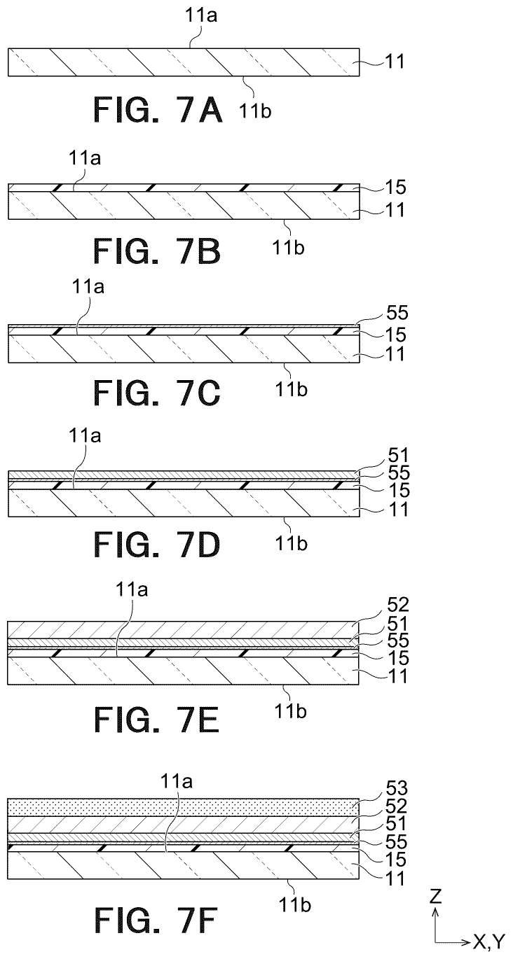

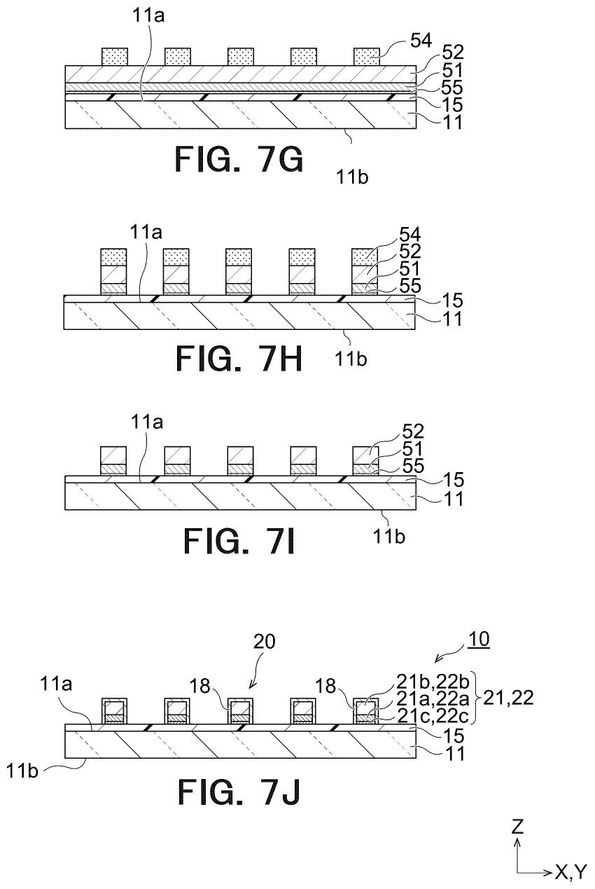

A method for manufacturing the wiring board 10 according to the present embodiment is described now with reference to FIG. 7A to FIG. 7J.

First, as illustrated in FIG. 7A, the substrate 11 having the first surface 11a and the second surface 11b positioned opposite to the first surface 11a is prepared. The substrate 11 has transparency.

As illustrated in FIG. 7B, the primer layer 15 is then formed on the substrate 11. The primer layer 15 may be formed over substantially the entire first surface 11a of the substrate 11. The primer layer 15 may be formed with roll coating, gravure coating, reverse gravure coating, micro gravure coating, slot die coating, die coating, knife coating, inkjet coating, dispenser coating, kiss coating, spray coating, screen printing, offset printing, or flexographic printing.

Thereafter, the mesh wiring layers 20 each including the multiple first direction wires 21 and the multiple second direction wires 22 that couple the multiple first direction wires 21 are formed on the primer layer 15.

As illustrated in FIG. 7C, first, a first metal film 55 is laminated on substantially the entire surface of the primer layer 15. The first metal film 55 is used to form the first dark color layers 21c and 22c. The first metal film 55 may be formed by sputtering or vapor deposition from, for example, copper or the like, an alloy of copper or the like, a nitride or an oxide of a single metal such as copper or the like, or a nitride or an oxide of an alloy of copper or the like. The first metal film 55 may have a thickness greater than or equal to 10 nm and less than or equal to 1000 nm. In the present embodiment, the first metal film 55 may contain copper.

As illustrated in FIG. 7D, the second metal film 51 is laminated on substantially the entire surface of the first metal film 55. This second metal film 51 is used to form the first metal layers 21a and 22a. The second metal film 51 may be formed by, for example, sputtering. The second metal film 51 may have a thickness greater than or equal to 10 nm and less than or equal to 1000 nm. In the present embodiment, the second metal film 51 may contain copper.

As illustrated in FIG. 7E, the third metal film 52 is then laminated on the second metal film 51. The third metal film 52 is used to form the second metal layers 21b and 22b. The third metal film 52 may be formed by electroplating using the second metal film 51 as a seed layer. The third metal film 52 may have a thickness greater than or equal to 50 nm and less than or equal to 4990 nm. In the present embodiment, the third metal film 52 may contain copper. The process of laminating the above first metal film 55 (FIG. 7C) and the process of laminating the second metal film 51 (FIG. 7D) may be performed in a vacuum chamber not illustrated. In contrast, the process of laminating the third metal film 52 (FIG. 7E) may be performed outside a vacuum chamber not illustrated.

Subsequently, as illustrated in FIG. 7F, a photo-curable insulating resist 53 is applied to substantially the entire surface of the third metal film 52. An example of this photo-curable insulating resist 53 includes an organic resin such as acrylic resin or epoxy resin.

Subsequently, as illustrated in FIG. 7G, an insulating layer 54 is formed by photolithography. In this case, the photo-curable insulating resist 53 is patterned by photolithography to form the insulating layer 54 (resist pattern). At this time, the insulating layer 54 is formed to expose portions of the third metal film 52 corresponding to the first direction wires 21 and the second direction wires 22.

Subsequently, as illustrated in FIG. 7H, portions of the third metal film 52, the second metal film 51, and the first metal film 55 on the first surface 11a of the substrate 11, not covered with the insulating layer 54, are removed. In this case, the third metal film 52, the second metal film 51, and the first metal film 55 are etched to expose the first surface 11a of the substrate 11 through wet etching using ferric chloride, cupric chloride, strong acid such as sulfuric acid or hydrochloric acid, persulfate, hydrogen peroxide, a solution of any of these, or a combination of any two or more of these. In this wet etching, a liquid with which the third metal film 52 and the second metal film 51 are treated and a liquid with which the first metal film 55 is treated may differ from each other.

Subsequently, as illustrated in FIG. 7I, the insulating layer 54 is removed. In this case, the insulating layer 54 on the third metal film 52 is removed by wet etching using a permanganate solution, N-methyl-2-pyrrolidone, an acid, or an alkaline solution, or dry etching using oxygen plasma.

Subsequently, as illustrated in FIG. 7J, the second dark color layers 18 are formed. In this case, the second dark color layers 18 may be formed by subjecting parts of the first metal film 55, the second metal film 51, and the third metal film 52 to darkening treatment (blackening treatment). Each second dark color layer 18 may be formed on the surfaces of the first metal film 55, the second metal film 51, and the third metal film 52 as a coating of a dark color material or a plating layer formed from, for example, nickel or chromium. Alternatively, the second dark color layers 18 may be formed by roughening the surfaces of the first metal film 55, the second metal film 51, and the third metal film 52.

In this manner, the wiring board 10 including the substrate 11, the primer layer 15 disposed on the first surface 11a of the substrate 11, the mesh wiring layers 20 disposed on the primer layer 15, and the second dark color layers 18 covering the mesh wiring layers 20 is obtained. In this case, the mesh wiring layers 20 include the first direction wires 21 and the second direction wires 22. At this time, the feeding points 40 may be formed by parts of the first metal film 55, the second metal film 51, and the third metal film 52.

Subsequently, the display device 61 is laminated on the wiring board 10 with the first transparent adhesive layer 95 and the second transparent adhesive layer 96 illustrated in FIG. 2 interposed therebetween, and thus the image display device 60 including the wiring board 10 and the display device 61 laminated on the wiring board 10 is obtained.

Now, operations of the present embodiment with the above structure are described.

As illustrated in FIG. 1 and FIG. 2, the wiring board 10 is incorporated in the image display device 60 including the display device 61. At this time, the wiring board 10 is disposed on the display device 61. The mesh wiring layers 20 in the wiring board 10 are electrically connected to the communication module 63 in the image display device 60 through the feeding points 40. The image display device 60 with this structure can thus perform communications by transmitting and receiving radio waves of a predetermined frequency using the mesh wiring layers 20.

In the present embodiment, the mesh wiring layers 20 include the first dark color layers 21c and 22c disposed on the primer layer 15, the first metal layers 21a and 22a disposed on the first dark color layers 21c and 22c, and the second metal layers 21b and 22b disposed on the first metal layers 21a and 22a. In this manner, forming the first metal layers 21a and 22a on the first dark color layers 21c and 22c and forming the second metal layers 21b and 22b on the first metal layers 21a and 22a can improve adhesion between the first dark color layers 21c and 22c and the first metal layers 21a and 22a and adhesion between the first metal layer and the second metal layer. Adhesion between the substrate 11 and the mesh wiring layers 20 can thus be improved. This improvement of adhesion between the substrate 11 and the mesh wiring layers 20 caused by the mesh wiring layers 20 including the first dark color layers 21c and 22c, the first metal layers 21a and 22a, and the second metal layers 21b and 22b is described using examples below.

In the present embodiment, the surface roughness Sa of the first dark color layers 21c and 22c is greater than or equal to 5 nm and less than or equal to 200 nm. This structure can thus reduce reflection of visible light at the rear surfaces of the first dark color layers 21c and 22c. In addition, the haze values of the first dark color layers 21c and 22c can be regulated without rising to an excessively high level, and this structure less easily allows an observer to visually discern the presence of the first dark color layers 21c and 22c. Thus, when the observer observes the wiring board 10 from the substrate 11, the mesh wiring layers 20 are less visually discernible to the naked eye of the observer.

In the present embodiment, the mesh wiring layers 20 include the first metal layers 21a and 22a disposed on the first dark color layers 21c and 22c and the second metal layers 21b and 22b disposed on the first metal layers 21a and 22a. This structure can effectively increase the height H₁ of the first direction wires 21 and the height H₂ of the second direction wires 22. Thus, the first direction wires 21 and the second direction wires 22 can reduce resistance.

In the present embodiment, the surface roughness Sa of the second dark color layers 18 is greater than or equal to 5 nm and less than or equal to 100 nm. This structure can reduce reflection of visible light at the surfaces of the second dark color layers 18. In this structure, the haze values of the second dark color layers 18 can be regulated without rising to an excessively high level, and this structure less easily allows an observer to visually discern the presence of the second dark color layers 18. Thus, each mesh wiring layer 20 covered with the corresponding second dark color layer 18 is less visually discernible to the naked eye of an observer.

In the present embodiment, the wiring board 10 includes the substrate 11, the primer layer 15 disposed on the substrate 11, the mesh wiring layers 20 disposed on the primer layer 15, and the second dark color layers 18 covering the mesh wiring layers 20. The substrate 11 has transparency. In addition, each mesh wiring layer 20 includes a conductor forming an opaque electrically conductive layer and a mesh pattern including a large number of apertures 23. Thus, the wiring board 10 maintains transparency. In this structure, when the wiring board 10 is disposed on the display device 61, the display device 61 is visually discernible through the apertures 23 in the mesh wiring layers 20, and the visibility of the display device 61 is not impaired.

Subsequently, a wiring board according to one or more modification examples of the first embodiment is described.

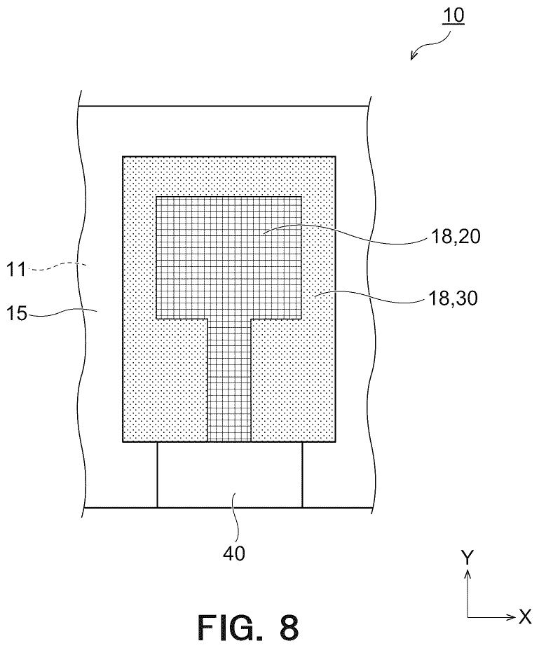

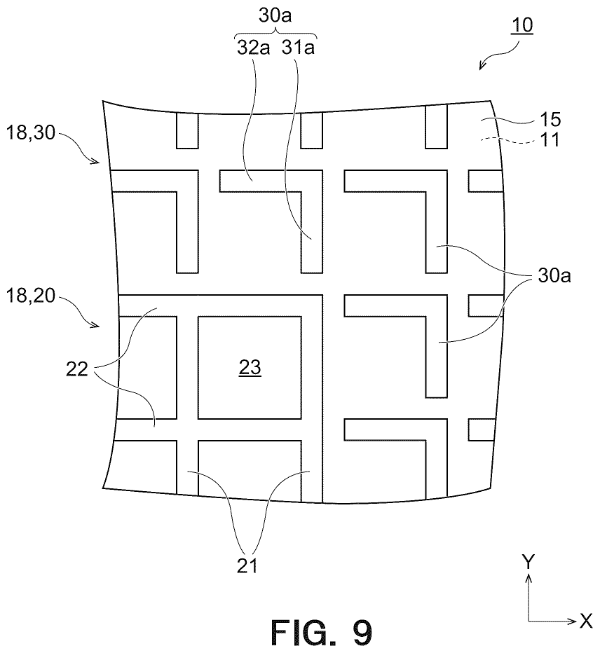

FIG. 8 and FIG. 9 illustrate a wiring board according to a first modification example of the first embodiment. The modification example illustrated in FIG. 8 and FIG. 9 differs from the above embodiment illustrated in FIG. 1 to FIG. 7J in that it includes a dummy wiring layer 30 disposed around each mesh wiring layer 20, and other components in the modification are substantially the same as the above embodiment. In FIG. 8 and FIG. 9, like or corresponding components in the embodiment illustrated in FIG. 1 to FIG. 7J are denoted by like reference signs, and are not described in detail.

The wiring board 10 illustrated in FIG. 8 includes the dummy wiring layer 30 around each mesh wiring layer 20. The dummy wiring layer 30 may be covered with the corresponding second dark color layer 18. Unlike the mesh wiring layers 20, the dummy wiring layer 30 does not substantially function as an antenna.

As illustrated in FIG. 9, the dummy wiring layer 30 is formed from a pattern of dummy wires 30a having a predetermined unit pattern shape. More specifically, the dummy wiring layer 30 includes multiple dummy wires 30a of the same shape, and each of the dummy wires 30a is electrically separate from the corresponding mesh wiring layer 20 (the first direction wires 21 and the second direction wires 22). The multiple dummy wires 30a are arranged regularly throughout the entire area of the dummy wiring layer 30. The multiple dummy wires 30a are spaced apart from each other in the plan direction, and protrude upward from the substrate 11. More specifically, each dummy wire 30a is electrically separate from the corresponding mesh wiring layer 20, the corresponding feeding point 40, and other dummy wires 30a. Each dummy wire 30a has a substantially L shape in a plan view.

In this case, each dummy wire 30a has a shape that lacks a part of the unit pattern shape (refer to FIG. 4) of the above mesh wiring layers 20. Thus, the difference between the mesh wiring layers 20 and the dummy wiring layer 30 is less visually distinguishable, and the mesh wiring layers 20 disposed on the substrate 11 are thus less visually discernible.

As illustrated in FIG. 9, the dummy wires 30a extend parallel to the first direction wires 21 or the second direction wires 22. More specifically, each dummy wire 30a includes a first portion 31a extending parallel to the first direction wires 21, and a second portion 32a extending parallel to the second direction wires 22. The first portion 31a has a shape that lacks a part of one first direction wire 21. The second portion 32a has a shape that lacks a part of one second direction wire 22. Other portions of the first portion 31a and the second portion 32a are the same as those in the first direction wires 21 and the second direction wires 22, and thus are not described in detail. As described above, the dummy wires 30a extend parallel to the first direction wires 21 or the second direction wires 22, and the mesh wiring layers 20 disposed on the substrate 11 are thus further less visually discernible. The aperture ratio of the dummy wiring layers 30 may be the same as or different from the aperture ratio of the mesh wiring layers 20. When the aperture ratio of the dummy wiring layers 30 is different from the aperture ratio of the mesh wiring layers 20, the aperture ratio of the dummy wiring layers 30 may be close to the aperture ratio of the mesh wiring layers 20.

In this manner, when the dummy wiring layer 30 electrically separate from each mesh wiring layer 20 is disposed around the mesh wiring layer 20, the outer periphery of the mesh wiring layer 20 is indistinguishable. The mesh wiring layers 20 on the surface of the image display device 60 are thus less visually discernible, and a user of the image display device 60 can less visually discern the mesh wiring layers 20 with the naked eye.

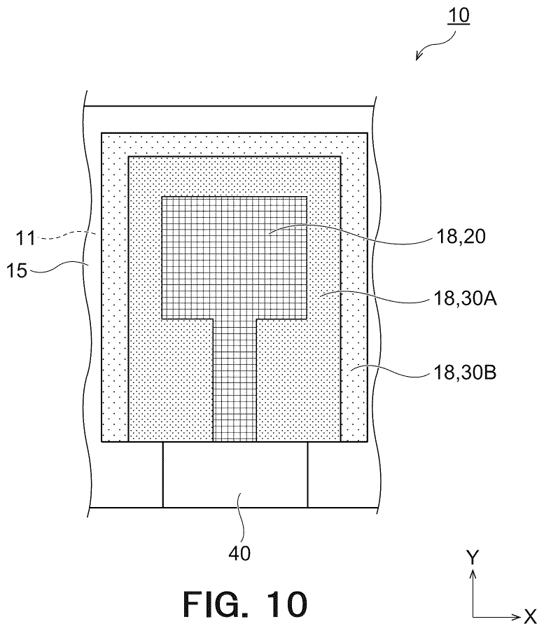

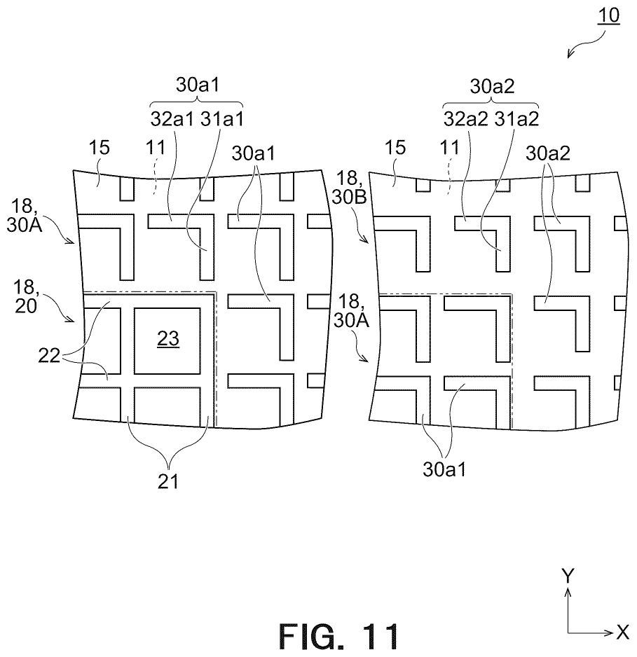

FIG. 10 and FIG. 11 illustrate a wiring board according to a second modification example of the first embodiment. The modification example illustrated in FIG. 10 and FIG. 11 differs from the embodiments illustrated in FIG. 1 to FIG. 9 in that it includes two or more dummy wiring layers 30A and 30B that differ in aperture ratio and that are disposed around the mesh wiring layers 20, and other components are substantially the same as those in the embodiments illustrated in FIG. 1 to FIG. 9. In FIG. 10 and FIG. 11, like or corresponding components in the embodiments illustrated in FIG. 1 to FIG. 9 are denoted by like reference signs, and are not described in detail.

The wiring board 10 illustrated in FIG. 10 includes multiple (in this example, two) dummy wiring layers 30A and 30B (a first dummy wiring layer 30A and a second dummy wiring layer 30B) having different aperture ratios disposed around the mesh wiring layers 20. More specifically, the first dummy wiring layer 30A is disposed around each mesh wiring layer 20, and the second dummy wiring layer 30B is disposed around the first dummy wiring layer 30A. The dummy wiring layers 30A and 30B may be covered with the corresponding second dark color layer 18. Unlike the mesh wiring layers 20, the dummy wiring layers 30A and 30B do not substantially function as antennas.

As illustrated in FIG. 11, the first dummy wiring layer 30A includes a pattern of dummy wires 30a1 having a predetermined unit pattern shape. The second dummy wiring layer 30B includes a pattern of dummy wires 30a2 having a predetermined unit pattern shape. More specifically, the dummy wiring layers 30A and 30B include multiple dummy wires 30a1 and 30a2 of the same shapes, and each of the dummy wires 30a1 and 30a2 is electrically separate from the corresponding one of the mesh wiring layers 20. The dummy wires 30a1 and 30a2 are regularly arranged throughout the entire surfaces of the dummy wiring layers 30A and 30B. The dummy wires 30a1 and 30a2 are spaced apart from one another in the plan direction, and protrude upward from the substrate 11. Each of the dummy wires 30a1 and 30a2 is electrically separate from the corresponding mesh wiring layer 20, the feeding point 40, and the other dummy wires 30a1 and 30a2. Each of the dummy wires 30a1 and 30a2 has a substantially L shape in a plan view.

In this case, each of the dummy wires 30a1 and 30a2 has a shape that lacks a part of the unit pattern shape (refer to FIG. 4) of the above mesh wiring layers 20. The difference between each mesh wiring layer 20 and the first dummy wiring layer 30A and the difference between the first dummy wiring layer 30A and the second dummy wiring layer 30B are thus less visually distinguishable, and the mesh wiring layers 20 disposed on the substrate 11 are thus less visually discernible. As illustrated in FIG. 11, the dummy wires 30a1 and 30a2 extend parallel to the first direction wires 21 or the second direction wires 22. More specifically, each of the dummy wires 30a1 includes a first portion 31a1 that extends parallel to the first direction wires 21, and a second portion 32a1 that extends parallel to the second direction wires 22. Each of the dummy wires 30a2 includes a first portion 31a2 that extends parallel to the first direction wires 21, and a second portion 32a2 that extends parallel to the second direction wires 22.

Each of the dummy wires 30a1 in the first dummy wiring layer 30A has a larger area than each of the dummy wires 30a2 in the second dummy wiring layer 30B. In this case, the wire width of each dummy wire 30a1 is the same as the wire width of each dummy wire 30a2, but the wire width of each dummy wire 30a1 may be greater than the wire width of each dummy wire 30a2. Other components of the dummy wires 30a1 and 30a2 are the same as the dummy wires 30a in the first modification example, and thus are not described in detail herein.

In the present modification example, the aperture ratios of each mesh wiring layer 20 and the two or more dummy wiring layers 30A and 30B may increase stepwise from the mesh wiring layer 20 toward the dummy wiring layers 30A and 30B, in a direction extending away from the mesh wiring layer 20. In other words, the dummy wiring layers may have aperture ratios that gradually increase from the dummy wiring layer located closer to the mesh wiring layer 20. In this case, the first dummy wiring layer 30A may have a larger aperture ratio than the mesh wiring layers 20. The second dummy wiring layer 30B may have a larger aperture ratio than the first dummy wiring layer 30A. This structure can make the outer peripheries of the mesh wiring layers 20 and the dummy wiring layers 30A and 30B more indistinguishable. The mesh wiring layers 20 on the surface of the image display device 60 are thus further less visually discernible.

Providing the dummy wiring layers 30A and 30B electrically separate from the mesh wiring layers 20 in this manner can make the outer peripheries of the mesh wiring layers 20 more indistinguishable. The mesh wiring layers 20 on the surface of the image display device 60 are thus further less visually discernible, and a user of the image display device 60 can less visually discern the mesh wiring layers 20 with the naked eye. Alternatively, three or more dummy wiring layers with different aperture ratios may be disposed around each mesh wiring layer 20.

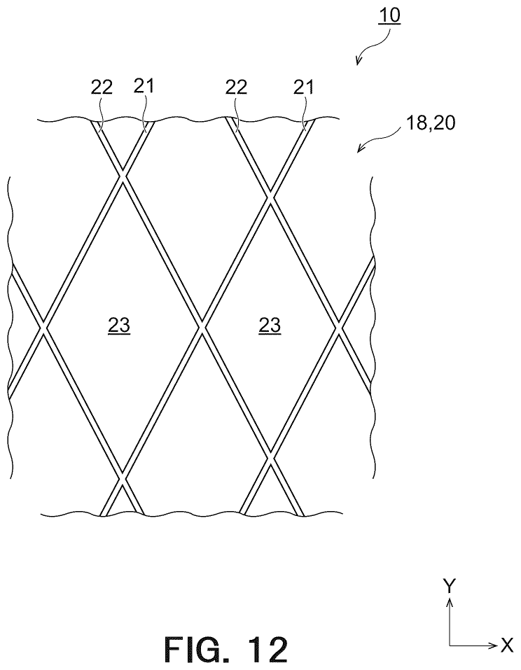

FIG. 12 illustrates a wiring board according to a third modification example of the first embodiment. The modification example illustrated in FIG. 12 differs from the embodiments illustrated in FIG. 1 to FIG. 11 in the plan shape of the mesh wiring layers 20, and other components are substantially the same as those in the embodiments illustrated in FIG. 1 to FIG. 11. In FIG. 12, like or corresponding components in the embodiments illustrated in FIG. 1 to FIG. 11 are denoted by like reference signs, and are not described in detail.

FIG. 12 is an enlarged plan view of a mesh wiring layer 20 according to a third modification example. In FIG. 12, the first direction wires 21 and the second direction wires 22 intersect obliquely (not orthogonally), and the apertures 23 have a rhombus shape in a plan view. Although the first direction wires 21 and the second direction wires 22 are parallel to neither the X direction nor the Y direction, either the first direction wires 21 or the second direction wires 22 may be parallel to the X direction or the Y direction.

### EXAMPLES

Specific examples of the present embodiment are described now.

### Example 1

A wiring board having a structure illustrated in FIG. 3 was fabricated. In this case, a substrate formed from polyethylene terephthalate with a thickness of 100 μm was used as a substrate of the wiring board. Polyester resin with a thickness of 0.1 μm was used as a primer layer.

The first direction wires and the second direction wires of a mesh wiring layer were formed on the primer layer. In this case, as a first metal film (a first dark color layer), an evaporated film of copper nitride with a thickness of 0.1 μm was formed by vapor deposition on the polyester resin serving as a primer layer. As a second metal film (a first metal layer), an evaporated film of copper with a thickness of 0.1 μm was formed by vapor deposition on the first metal film. As a third metal film (a second metal layer), a copper plating layer with a thickness of 1.0 μm was formed by plating on the second metal film. Thereafter, a photo-curable insulating resist was formed on the third metal film to form a photoresist pattern that covers a pattern serving as the first direction wires and the second direction wires with an exposure and development process. The resultant was then subjected to etching with a ferric chloride solution, and then to resist removal with an alkali solution. The first direction wires and the second direction wires had a wire width of 2.0 μm, and were arranged at a pitch of 100 μm. The first dark color layer and the first metal layer were formed in a vacuum chamber, and the second metal layer was formed outside the vacuum chamber. The surface roughness Sa of the first dark color layer was 17 nm.

### (1) Visibility Evaluation Test

Subsequently, visibility of the mesh wiring layers in the wiring board was checked. In this test, the mesh wiring layers were observed from the substrate (in the negative Z direction).

### (2) Adhesion Evaluation Test

Subsequently, adhesion of the mesh wiring layer to the substrate was evaluated. In this test, first, adhesive tape (Cellotape (registered trademark) from Nichiban Co., Ltd.) was bonded to the mesh wiring layers. The adhesive tape was then removed from the wiring board, and whether the mesh wiring layer adhered to the adhesive tape was checked.

### Comparative Example 1

The visibility evaluation test and the adhesion evaluation test were conducted in the same manner on Example 1 and Comparative Example 1, which differs from Example 1 in that the second metal layer was directly formed on the first dark color layer without forming the first metal layer and the thickness of the second metal layer was 1.1 μm.

Table 1 shows the above test results. In the column of visibility evaluation test in Table 1, “A (excellent)” indicates that the mesh wiring layers were not visually discernible to the naked eye. In the column of adhesion evaluation test in Table 1, “A (excellent)” indicates that the mesh wiring layers did not adhere to the adhesive tape. “B (poor)” indicates that the mesh wiring layers adhered to the adhesive tape.

TABLE 1

| | Visibility Evaluation | Adhesion Evaluation |
|---|---|---|
| | Test | Test |
| Example 1 | A | A |
| Comparative Example 1 | A | B |

As shown in Table 1, the test results reveal that, in the wiring board according to Example 1 and the wiring board according to Comparative Example 1, the mesh wiring layers were not visually discernible to the naked eye. The test results reveal that the present embodiment can make the mesh wiring layers less visually discernible to the naked eye.

As shown in Table 1, the test results reveal that, in the wiring board according to Comparative Example 1, the mesh wiring layers adhered to the adhesive tape. More specifically, in the wiring board according to Comparative Example 1, the second metal layer detached from the first dark color layer, and adhered to the adhesive tape. In contrast, in the wiring board according to Example 1, the mesh wiring layers did not adhere to the adhesive tape. More specifically, the test results reveal that, when the first metal layer is formed on the first dark color layer subjected to the darkening process in the same manner as in the first dark color layer (for example, vapor deposition), the adhesion between the first dark color layer and the first metal layer can be improved. The test results also reveal that, when the second metal layer containing the same metal as that in the first metal layer is formed on the first metal layer not subjected to the darkening process, the adhesion between the first metal layer and the second metal layer can be improved. The test results thus reveal that, in the present embodiment, adhesion between the substrate and the mesh wiring layer can be improved.

### Second Embodiment

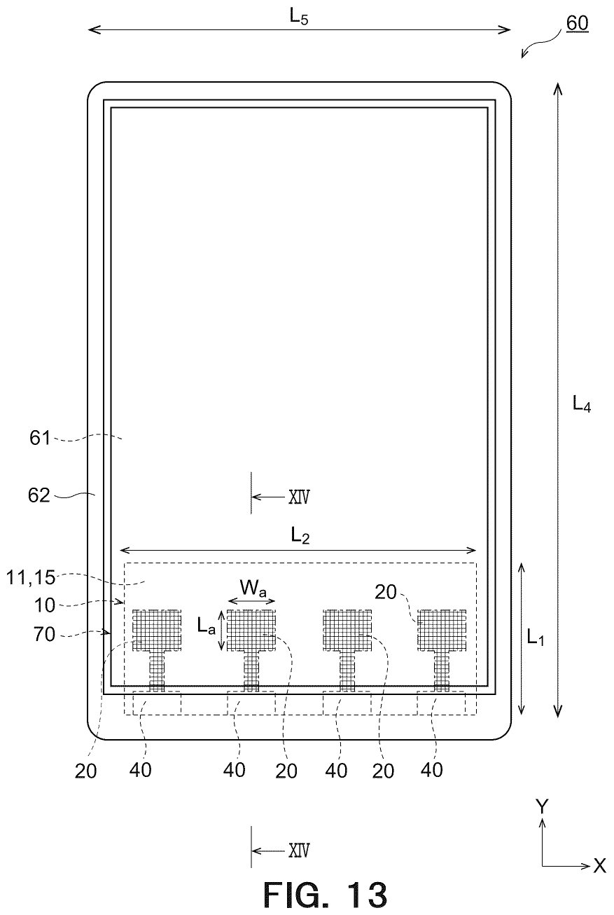

With reference now to FIG. 13 to FIG. 19I, a second embodiment is described. FIG. 13 to FIG. 19I illustrate the second embodiment. In FIG. 13 to FIG. 19I, like or corresponding components in the first embodiment illustrated in FIG. 1 to FIG. 12 are denoted by like reference signs, and may not be described in detail.

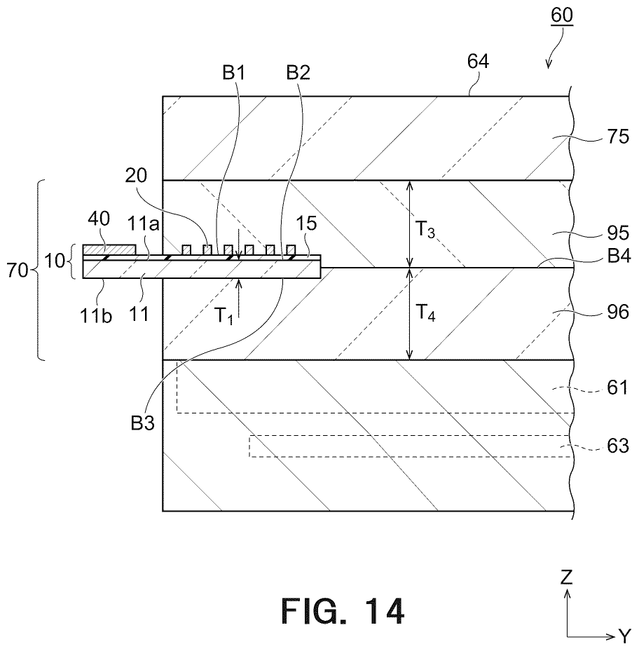

With reference to FIG. 13 and FIG. 14, the structure of an image display device according to the present embodiment is described.

As illustrated in FIG. 13 and FIG. 14, an image display device 60 according to the present embodiment includes a wiring board 10 and a display device 61 laminated on the wiring board 10. The wiring board 10 constitutes an image-display-device multilayer body 70 together with a first transparent adhesive layer 95 and a second transparent adhesive layer 96.

The wiring board 10 includes a substrate 11 having transparency and mesh wiring layers 20 disposed on a first surface 11a, described later, of the substrate 11. The wiring board 10 may further include a primer layer 15 disposed between the substrate 11 and the mesh wiring layers 20, and feeding points 40. As illustrated in FIG. 14, the substrate 11 has a first surface 11a and a second surface 11b positioned opposite to the first surface 11a. The primer layer 15 is disposed on the first surface 11a of the substrate 11. The mesh wiring layers 20 are disposed on the primer layer 15. The feeding points 40 are electrically connected to the mesh wiring layers 20. A communication module 63 is also disposed in the negative Z direction with respect to the display device 61. The image-display-device multilayer body 70, the display device 61, and the communication module 63 are accommodated in the housing 62.

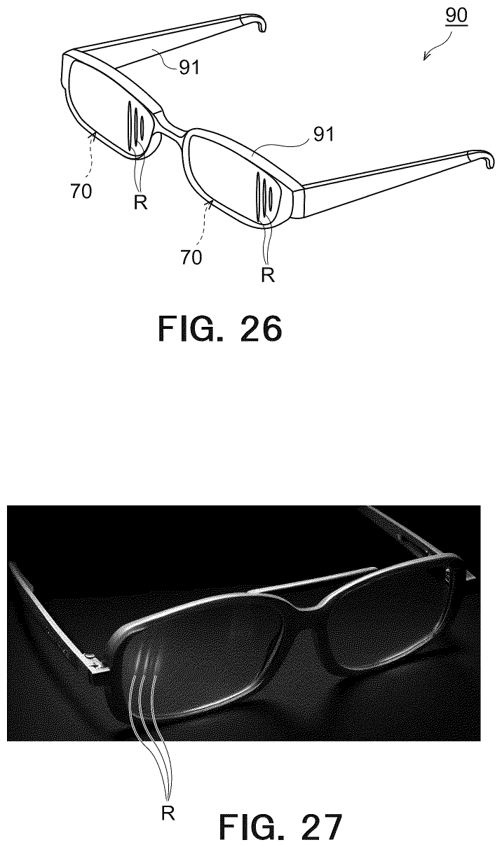

The image-display-device multilayer body 70 is then described in detail. As described above, the image-display-device multilayer body 70 includes the wiring board 10, the first transparent adhesive layer 95, and the second transparent adhesive layer 96. A cover glass 75 is disposed on the wiring board 10 with the first transparent adhesive layer 95 interposed therebetween. Between the first transparent adhesive layer 95 and the cover glass 75, a decorating film and a polarizing plate not illustrated may be disposed. Alternatively, the image-display-device multilayer body 70 may be attached to a frame 91 (refer to FIG. 26), and installed in a head mount display (smart glasses).

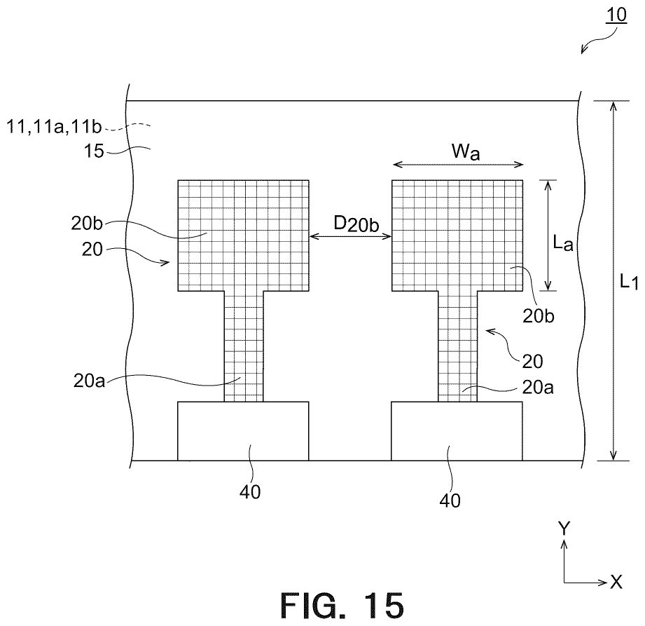

With reference to FIG. 15 to FIG. 18, the structure of the wiring board is described now. FIG. 15 to FIG. 18 illustrate the wiring board according to the present embodiment.

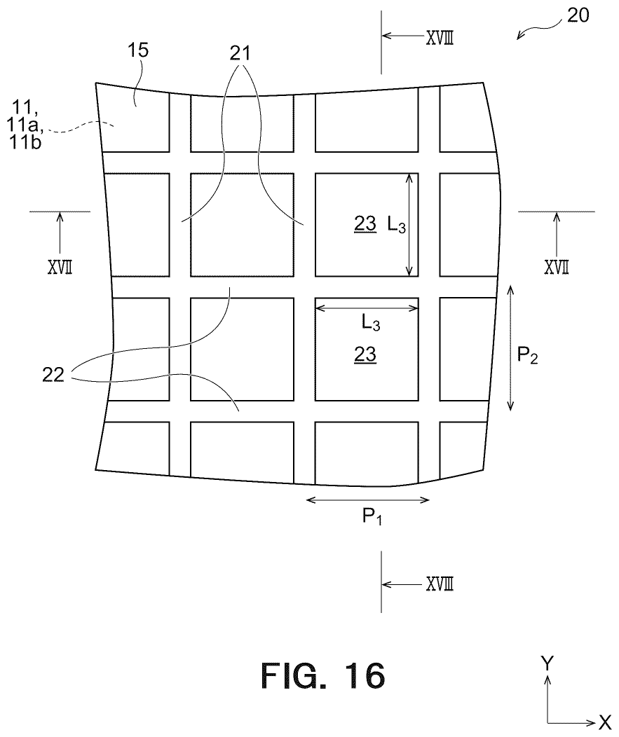

The wiring board 10 according to FIG. 15 and FIG. 16 is a board included in the image display device 60 (refer to FIG. 13 and FIG. 14). The wiring board 10 may be disposed closer to the light emerging surface 64 with respect to the display device 61, and between the first transparent adhesive layer 95 and the second transparent adhesive layer 96. As described above, the wiring board 10 with this structure includes the substrate 11 having transparency, the primer layer 15 disposed on the substrate 11, and the mesh wiring layers 20 disposed on the primer layer 15. The feeding points 40 are electrically connected to the mesh wiring layers 20.

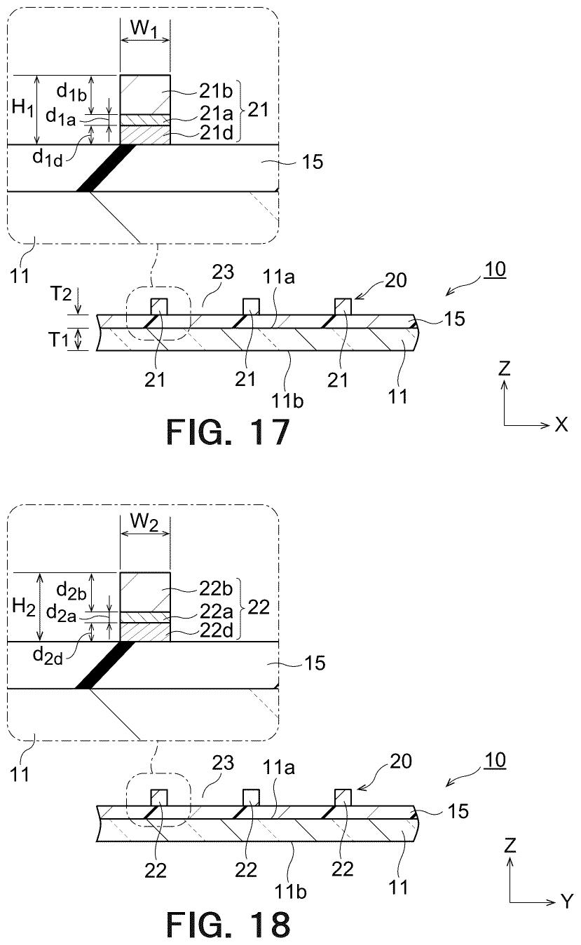

As illustrated in FIG. 17 and FIG. 18, the mesh wiring layers 20 include black layers 21d and 22d disposed on the primer layer 15, first metal layers 21a and 22a disposed on the black layers 21d and 22d, and second metal layers 21b and 22b disposed on the first metal layers 21a and 22a. More specifically, each first direction wire 21 includes the black layer 21d disposed on the primer layer 15, the first metal layer 21a disposed on the black layer 21d, and the second metal layer 21b disposed on the first metal layer 21a. Each second direction wire 22 includes the black layer 22d disposed on the primer layer 15, the first metal layer 22a disposed on the black layer 22d, and the second metal layer 22b disposed on the first metal layer 22a.

Among these layers, the black layers 21d and 22d are layers to reduce reflection of visible light that is incident on the mesh wiring layers 20 from the substrate 11 to make the mesh wiring layers 20 less visually discernible to the naked eye.

The black layers 21d and 22d may be layers with, for example, a dark color such as black. The black layers 21d and 22d may be formed from any material that can exert intended light shielding performance. In the present embodiment, the black layers 21d and 22d contain resin. When the black layers 21d and 22d contain resin, the wire width W₁ of each first direction wire 21 and the wire width W₂ of each second direction wire 22 can be easily reduced to less than or equal to 5.0 μm. In this case, the black layers 21d and 22d may be cured products obtained by adding a black coloring material to a binder resin. As an example binder resin used as the black layers 21d and 22d, a material that allows a black coloring material to be dispersed therein is preferably usable. Examples used as the binder resin include photoconductive resins containing reactive vinyl groups such as acrylate-based resins, methacrylate-based resins, polyvinyl cinnamate-based resins, or cyclized rubber. The black layers 21d and 22d may contain a dye or a pigment as a black coloring material. More specifically, the black layers 21d and 22d may contain a pigment such as carbon black or titanium black.

The surface roughness Sa (arithmetic mean height of the surface) of the black layers 21d and 22d may be greater than or equal to 5 nm and less than or equal to 200 nm. When the surface roughness Sa of the black layers 21d and 22d is greater than or equal to 5 nm, reflection of visible light at the black layers 21d and 22d can be reduced. The mesh wiring layers 20 are thus less visually discernible to the naked eye of an observer. When the surface roughness Sa of the black layers 21d and 22d is less than or equal to 200 nm, the haze values of the black layers 21d and 22d can be regulated without rising to an excessively high level. This structure thus less easily allows an observer to visually discern the presence of the black layers 21d and 22d. The mesh wiring layers 20 are thus less visually discernible to the naked eye of the observer. To measure the surface roughness Sa of the black layers 21d and 22d, the surface roughness Sa of the rear surfaces of the black layers 21d and 22d is measured based on ISO 25178 using a laser microscope (VK-X1000 from Keyence Corporation). To measure the surface roughness Sa of the black layers 21d and 22d, first, the wiring board 10 is set to the laser microscope to be irradiated with laser beams from the second surface 11b of the substrate 11. The magnifying power of the objective lens is set to 50. In this case, the measurement area is approximately 270 μm×200 μm. The wiring board 10 is then irradiated with laser beams from the second surface 11b of the substrate 11. The surface roughness Sa of the black layers 21d and 22d is thus measured. With this measurement method, the surface roughness Sa of the black layers 21d and 22d can be measured even after the first metal layers 21a and 22a and the second metal layers 21b and 22b are laminated on the black layers 21d and 22d.

Thicknesses d_{1d} and d_{2d} of the black layers 21d and 22d may be greater than or equal to 0.2 μm and less than or equal to 1.0 μm, greater than or equal to 0.3 μm and less than or equal to 0.8 μm, or greater than or equal to 0.4 μm and less than or equal to 0.6 μm. When the thicknesses d₁ₐ and d₂ₐ of the black layers 21d and 22d are greater than or equal to 0.2 μm, adhesion between the primer layer 15 and the black layers 21d and 22d and adhesion between the black layers 21d and 22d and the first metal layers 21a and 22a can be improved. When the thicknesses d_{1d} and d_{2d} of the black layers 21d and 22d are less than or equal to 1.0 μm, the haze values of the black layers 21d and 22d can be regulated without rising to an excessively high level, and this structure less easily allows an observer to visually discern the presence of the black layers 21d and 22d. The mesh wiring layers 20 are thus less visually discernible to the naked eye of an observer.

Also in the present embodiment, the first metal layers 21a and 22a and the second metal layers 21b and 22b may have different crystal properties. The first metal layers 21a and 22a and the second metal layers 21b and 22b may differ in at least one of crystal fraction, crystal structure, crystallite size, and crystal plane interval. For example, the first metal layers 21a and 22a may have a diffraction angle 2θ of the (111) plane measured using Cu Kα radiation as an X-ray source greater than a diffraction angle 2θ of the (111) plane of the second metal layers 21b and 22b. For example, the first metal layers 21a and 22a may have a crystal property in which the diffraction angle 2θ of the (111) plane measured using Cu Kα radiation as an X-ray source is less than or equal to 43.430°. Thus, the adhesion between the black layers 21d and 22d and the first metal layers 21a and 22a can be improved. In this case, the above diffraction angle 2θ may be less than or equal to 43.420, or less than or equal to 43.410°. Although the lower limit of the above diffraction angle 2θ is not particularly limited, the lower limit of the diffraction angle 2θ may be set greater than or equal to 43.250°, greater than or equal to 43.300°, or greater than or equal to 43.350°. The diffraction angle can be measured using an X-ray diffractometer (Smart Lab, 9-kW type from Rigaku Corporation). The diffraction angle 2θ of the (111) plane of the first metal layers 21a and 22a and the diffraction angle 2θ of the (111) plane of the second metal layers 21b and 22b are measured at the feeding points 40. As described later, concurrently with the first metal layers 21a and 22a and the second metal layers 21b and 22b, the feeding points 40 are formed from parts of a first metal film 501 forming the first metal layers 21a and 22a and parts of a second metal film 502 forming the second metal layers 21b and 22b. Thus, the diffraction angle 2θ of the (111) plane of the first metal layers 21a and 22a and the diffraction angle 2θ of the (111) plane of the second metal layers 21b and 22b can be measured at the feeding points 40. In this case, for example, the diffraction angle 2θ of the (111) plane of the first metal layers 21a and 22a can be more accurately measured compared to the case where, for example, the diffraction angle 2θ of the (111) plane of the first metal layers 21a and 22a is measured in the mesh wiring layers 20 in which the wire widths W₁ and W₂ are relatively narrow. Measurement conditions are described below.

Measurement mode: 2θ/θ measurement (Out-of-Plane)

X-ray source: Cu-Kα, 45 kV, 50 mA

Optical system: focusing

Incident optical system 1: solar slit, 5 deg

Incident optical system 2: variable slit (IS), 1 deg

Longitudinal restriction slit: 10 mm

Receiving optical system 1: variable slit (RS1), 1 deg, receiving slit (RS2), 0.3 mm

Receiving optical system 2: PSA OPEN/solar slit, 5 deg

Detector: scintillation counter

Measurement range: 35 to 80 deg

Step size: 0.02 deg

Measurement speed: 2.0 deg/min

The first metal layers 21a and 22a and the second metal layers 21b and 22b in the first direction wires 21 and the second direction wires 22 may be formed from any electroconductive metal material. In the present embodiment, the first metal layers 21a and 22a and the second metal layers 21b and 22b are formed from copper, but this is not the only possible example. The first metal layers 21a and 22a and the second metal layers 21b and 22b may be formed from, for example, a metal material such as gold, silver, copper, platinum, tin, aluminum, iron, or nickel, or an alloy containing any of these metals. The material of the first metal layers 21a and 22a and the material of the second metal layers 21b and 22b may be the same. In this structure, adhesion between the first metal layers 21a and 22a and the second metal layers 21b and 22b can be improved.

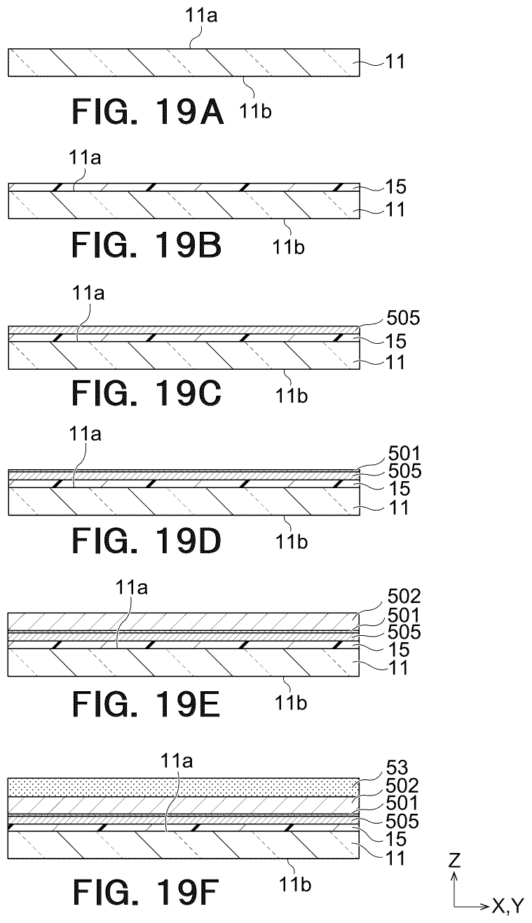

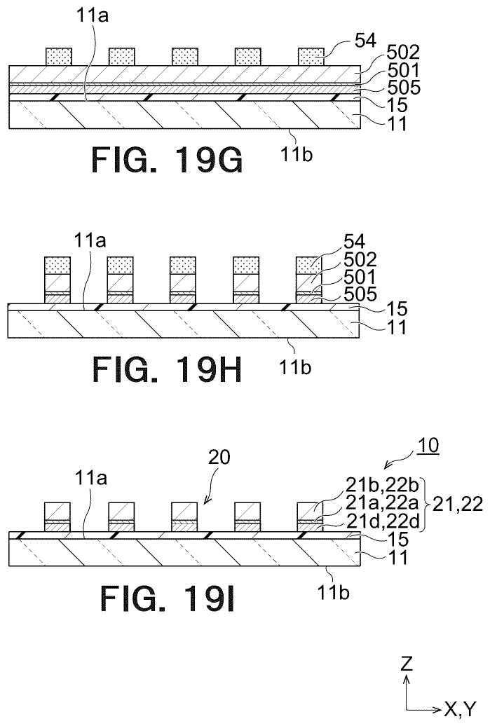

With reference now to FIG. 19A to FIG. 19I, a method for manufacturing the wiring board 10 according to the present embodiment is described.

First, as illustrated in FIG. 19A, the substrate 11 having the first surface 11a and the second surface 11b positioned opposite to the first surface 11a is prepared. The substrate 11 has transparency.

As illustrated in FIG. 19B, the primer layer 15 is then formed on the substrate 11. The primer layer 15 may be formed over substantially the entire first surface 11a of the substrate 11. The primer layer 15 may be formed with roll coating, gravure coating, reverse gravure coating, micro gravure coating, slot die coating, die coating, knife coating, inkjet coating, dispenser coating, kiss coating, spray coating, screen printing, offset printing, or flexographic printing.

Subsequently, the mesh wiring layers 20 including the multiple first direction wires 21 and the multiple second direction wires 22 coupling the multiple first direction wires 21 are disposed on the primer layer 15.

At this time, first, as illustrated in FIG. 19C, a resin film 505 is laminated on substantially the entire surface of the primer layer 15. The resin film 505 is a film used to form the black layers 21d and 22d. The resin film 505 may be formed by, for example, gravure printing using, for example, resin containing a dye or a pigment. The resin film 505 may have a thickness greater than or equal to 0.2 μm and less than or equal to 1.0 μm.

As illustrated in FIG. 19D, the first metal film 501 is laminated on substantially the entire surface of the resin film 505. The first metal film 501 is a film used to form the first metal layers 21a and 22a. The first metal film 501 may be formed by, for example, sputtering. The first metal film 501 may have a thickness greater than or equal to 10 nm and less than or equal to 1000 nm. In the present embodiment, the first metal film 501 may contain copper.

As illustrated in FIG. 19E, the second metal film 502 is then laminated on the first metal film 501. The second metal film 502 is a film used to form the second metal layers 21b and 22b. The second metal film 502 may be formed by electroplating using the first metal film 501 as a seed layer. The second metal film 502 may have a thickness greater than or equal to 50 nm and less than or equal to 4990 nm. In the present embodiment, the second metal film 502 may contain copper. The above process (FIG. 19D) of laminating the first metal film 501 may be performed in a vacuum chamber not illustrated. In contrast, the process (FIG. 19E) of laminating the second metal film 502 may be performed outside the vacuum chamber not illustrated.

Subsequently, as illustrated in FIG. 19F, the photo-curable insulating resist 53 is applied to substantially the entire surface of the second metal film 502. An example of the photo-curable insulating resist 53 includes an organic resin such as acrylic resin or epoxy resin.

As illustrated in FIG. 19G, the insulating layer 54 is then formed by photolithography. In this case, the photo-curable insulating resist 53 is patterned by photolithography to form the insulating layer 54 (resist pattern). At this time, the insulating layer 54 is formed to expose portions of the second metal film 502 corresponding to the first direction wires 21 and the second direction wires 22.

As illustrated in FIG. 19H, portions of the second metal film 502, the first metal film 501, and the resin film 505 positioned on the first surface 11a of the substrate 11 without being covered with the insulating layer 54 are then removed. At this time, the second metal film 502, the first metal film 501, and the resin film 505 are etched to expose the first surface 11a of the substrate 11 by wet etching using ferric chloride, cupric chloride, strong acid such as sulfuric acid or hydrochloric acid, persulfate, hydrogen peroxide, a solution of any of these, or a combination of any two or more of these. In this wet etching, a liquid with which the second metal film 502 and the first metal film 501 are treated and a liquid with which the resin film 505 is treated may differ from each other. Although not illustrated, as an example of other process details, to obtain a pattern similar to that of the resin film 505 in FIG. 19H, a pattern may be formed in advance on the resin film 505 by photolithography. In a process performed later, another layer may be laminated on the resin film 505.

As illustrated in FIG. 19I, the insulating layer 54 is then removed. In this case, the insulating layer 54 on the second metal film 502 is removed by wet etching using a permanganate solution, N-methyl-2-pyrrolidone, an acid, or an alkaline solution, or dry etching using oxygen plasma.

In this manner, the wiring board 10 including the substrate 11, the primer layer 15 disposed on the first surface 11a of the substrate 11, and the mesh wiring layers 20 disposed on the primer layer 15 is obtained. In this case, the mesh wiring layers 20 include the first direction wires 21 and the second direction wires 22. At this time, the feeding points 40 may be formed by parts of the first metal film 501 and the second metal film 502.

Subsequently, the display device 61 is laminated on the wiring board 10 with the first transparent adhesive layer 95 and the second transparent adhesive layer 96 illustrated in FIG. 14 interposed therebetween, and thus the image display device 60 including the wiring board 10 and the display device 61 laminated on the wiring board 10 is obtained.

Now, operations of the present embodiment with the above structure are described.

As illustrated in FIG. 13 and FIG. 14, the wiring board 10 is incorporated in the image display device 60 including the display device 61. At this time, the wiring board 10 is disposed on the display device 61. The mesh wiring layers 20 in the wiring board 10 are electrically connected to the communication module 63 in the image display device 60 with the feeding points 40. The image display device 60 with this structure can thus perform communications by transmitting and receiving radio waves of a predetermined frequency using the mesh wiring layers 20.

In the present embodiment, the mesh wiring layers 20 include the first direction wires 21 and the second direction wires 22. The first direction wires 21 and the second direction wires 22 include the black layers 21d and 22d containing resin, the first metal layers 21a and 22a disposed on the black layers 21d and 22d, and the second metal layers 21b and 22b disposed on the first metal layers 21a and 22a. The first direction wires 21 and the second direction wires 22 including the black layers 21d and 22d can reduce reflection of visible light that is incident on each mesh wiring layer 20 from the substrate 11. The mesh wiring layers 20 are thus less visually discernible to the naked eye.

When the black layers 21d and 22d contain resin, the wire width W₁ of each first direction wire 21 and the wire width W₂ of each second direction wire 22 can be easily reduced to less than or equal to 5.0 μm. More specifically, when the black layers are formed from metal, while the first direction wires 21 and other wires are formed, the black layers and portions between the black layers and the first metal layers 21a and 22a may be unintentionally etched. In this case, disconnection (or a wire break) of the first direction wires 21 or other wires may occur. In addition, due to the difference in etching rate between the black layers and the first metal layers 21a and 22a and other layers, the first metal layers 21a and 22a and other layers may be unintentionally removed, or the black layers may be unintentionally removed. In other words, when the black layers are formed from, for example, metal, the shapes of the layers may be difficult to control. In contrast, the black layers 21d and 22d (resin film 505) containing resin can improve the acid resistance of the resin film 505. Thus, to form the first direction wires 21 and the second direction wires 22 by etching, the shapes of the layers can be easily controlled by removing the black layers 21d and 22d with wet etching using, for example, an alkaline solution or dry etching. The wire width W₁ of each first direction wire 21 and the wire width W₂ of each second direction wire 22 can thus be reduced to less than or equal to 5.0 μm. The mesh wiring layers 20 are thus less visually discernible to the naked eye.

In the present embodiment, the mesh wiring layers 20 include the black layers 21d and 22d, the first metal layers 21a and 22a disposed on the black layers 21d and 22d, and the second metal layers 21b and 22b disposed on the first metal layers 21a and 22a. When the first metal layers 21a and 22a are formed on the black layers 21d and 22d and the second metal layers 21b and 22b are formed on the first metal layers 21a and 22a in this manner, adhesion between the black layers 21d and 22d and the first metal layers 21a and 22a and adhesion between the first metal layer and the second metal layer can be improved. Thus, adhesion between the substrate 11 and the mesh wiring layers 20 can be improved.

In the present embodiment, the mesh wiring layers 20 include the first metal layers 21a and 22a disposed on the black layers 21d and 22d and the second metal layers 21b and 22b disposed on the first metal layers 21a and 22a. This structure can effectively enhance the height H₁ of the first direction wires 21 and the height H₂ of the second direction wires 22. The first direction wires 21 and the second direction wires 22 thus can reduce resistance.

In the present embodiment, the wiring board 10 includes the substrate 11, the primer layer 15 disposed on the substrate 11, and the mesh wiring layers 20 disposed on the primer layer 15. The substrate 11 has transparency. In addition, each mesh wiring layer 20 includes a conductor that forms an opaque electrically conductive layer, and a mesh pattern formed from a large number of apertures 23. The wiring board 10 thus maintains transparency. In this structure, when the wiring board 10 is disposed on the display device 61, the display device 61 is visually discernible through the apertures 23 in the mesh wiring layers 20, and the visibility of the display device 61 is not impaired.

A wiring board according to one or more modification examples of the second embodiment is described now.

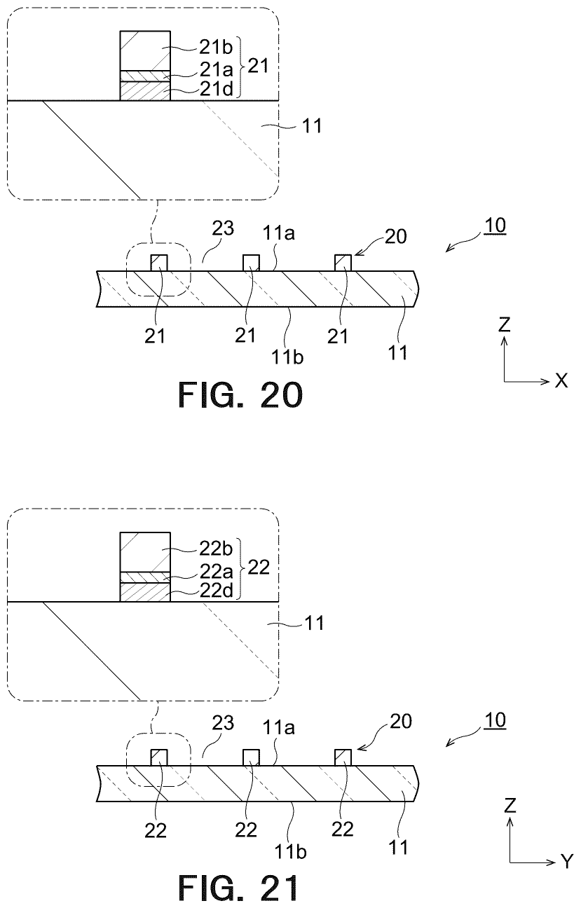

FIG. 20 and FIG. 21 illustrate a wiring board according to a first modification example of the second embodiment. The modification example illustrated in FIG. 20 and FIG. 21 differs from the above embodiment illustrated in FIG. 13 to FIG. 19I in that the wiring board 10 does not include the primer layer 15, and other components are substantially the same as those in the above embodiment illustrated in FIG. 13 to FIG. 19I. In FIG. 20 and FIG. 21, like or corresponding components in the embodiment illustrated in FIG. 13 to FIG. 19I are denoted by like reference signs, and are not described in detail.

The wiring board 10 illustrated in FIG. 20 and FIG. 21 does not include the primer layer 15 disposed on the substrate 11. In this case, for example, the black layers 21d and 22d improve adhesion between the mesh wiring layers 20 and the substrate 11. This structure can also improve adhesion between the substrate 11 and the mesh wiring layers 20.

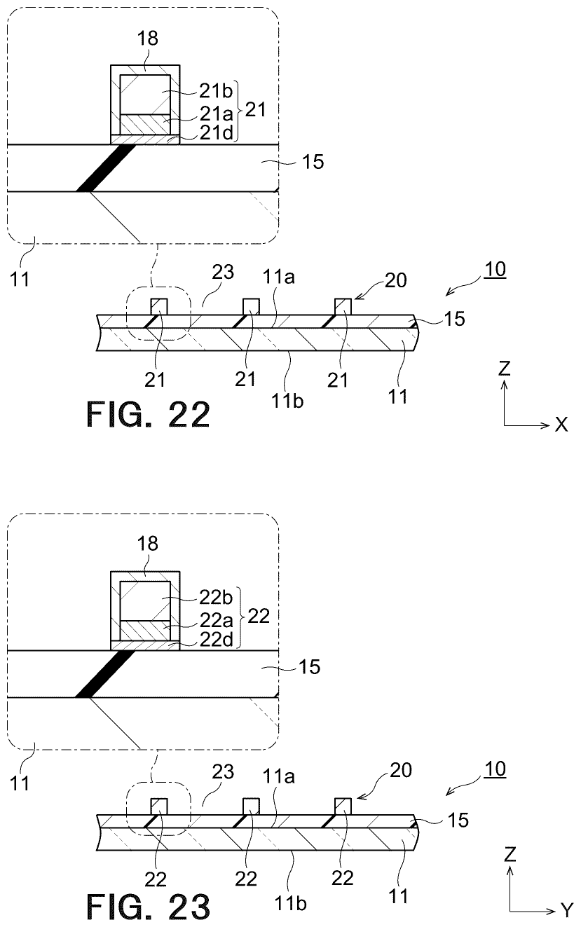

FIG. 22 and FIG. 23 illustrate a wiring board according to a second modification example of the second embodiment. The modification example illustrated in FIG. 22 and FIG. 23 differs from the above embodiments illustrated in FIG. 13 to FIG. 21 in that the wiring board 10 further includes dark color layers 18 covering the mesh wiring layers 20, and other components are substantially the same as those in the above embodiments illustrated in FIG. 13 to FIG. 21. In FIG. 22 and FIG. 23, like or corresponding components in the embodiments illustrated in FIG. 13 to FIG. 21 are denoted by like reference signs, and are not described in detail.

In the wiring board 10 illustrated in FIG. 22 and FIG. 23, the mesh wiring layers 20 are covered with the dark color layers 18. The dark color layers 18 are layers that reduce reflection of visible light at the mesh wiring layers 20 and make the mesh wiring layers 20 less visually discernible to the naked eye. Each dark color layer 18 covers side surfaces of the first metal layers 21a and 22a and the surfaces and side surfaces of the second metal layers 21b and 22b in the corresponding mesh wiring layer 20. In other words, each dark color layer 18 surrounds the first metal layers 21a and 22a and the second metal layers 21b and 22b to cover the entire area of the first metal layers 21a and 22a and the second metal layers 21b and 22b except for the rear surfaces of the first metal layers 21a and 22a. In the illustrated example, the black layers 21d and 22d are disposed on the rear surface (in the negative Z direction) of the dark color layer 18, and cover the rear surface of the dark color layer 18. Although not illustrated, the black layers 21d and 22d may not cover the rear surface of the dark color layer 18, and the dark color layer 18 may instead cover the side surfaces of the black layers 21d and 22d. The dark color layer 18 may cover the entire areas of the feeding points 40 except for the rear surfaces of the feeding points 40.

Each dark color layer 18 may be, for example, a layer with a dark color such as black. Each dark color layer 18 may be a layer with a rough surface.

The surface roughness Sa of the dark color layers 18 may be greater than or equal to 5 nm and less than or equal to 100 nm. When the surface roughness Sa of the dark color layers 18 is greater than or equal to 5 nm, reflection of visible light at the surfaces of the dark color layers 18 can be reduced. Thus, the mesh wiring layers 20 covered with the dark color layers 18 are less visually discernible to the naked eye of an observer. When the surface roughness Sa of the dark color layers 18 is less than or equal to 100 nm, the haze values of the dark color layers 18 can be regulated without rising to an excessively high level. This structure less easily allows an observer to visually discern the presence of the dark color layers 18. The mesh wiring layers 20 covered with the dark color layers 18 are thus less visually discernible to the naked eye of an observer. In this case, the surface roughness Sa is obtained based on ISO 25178 using a laser microscope (VK-X1000 from Keyence Corporation).

The dark color layers 18 may be formed from parts of the mesh wiring layers 20 or the feeding points 40 by, for example, subjecting parts of a metal material forming the mesh wiring layers 20 or the feeding points 40 to darkening treatment (blackening treatment). In this case, the dark color layers 18 may be layers formed from a metal oxide or a metal sulfide. Alternatively, each dark color layer 18 may be formed on the surface of the corresponding mesh wiring layer 20 or the corresponding feeding point 40 as a coating of a dark color material or a plating layer formed from, for example, nickel or chromium. Alternatively, each dark color layer 18 may be formed by roughening the surface of the corresponding mesh wiring layer 20 or the corresponding feeding point 40.

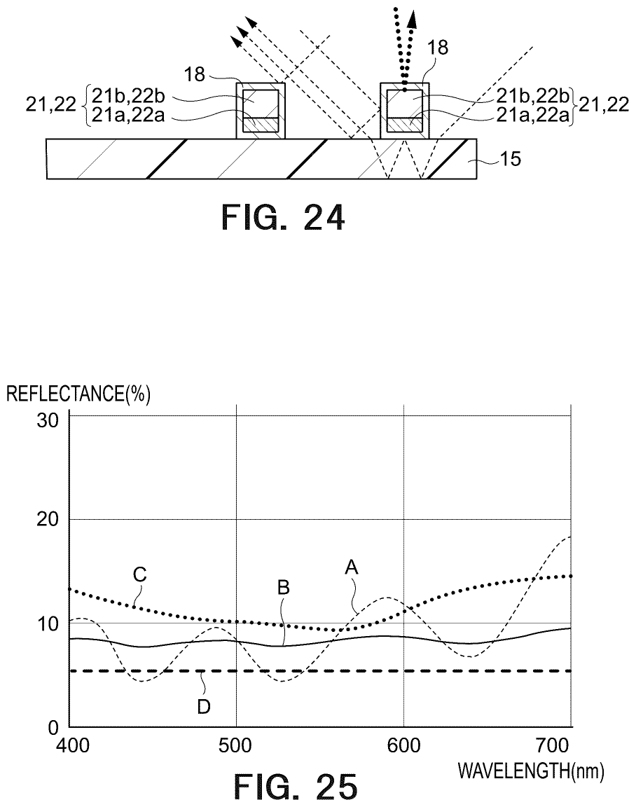

As described above, each dark color layer 18 covers the side surfaces of the first metal layers 21a and 22a and the surfaces and the side surfaces of the second metal layers 21b and 22b in the mesh wiring layers 20. In contrast, as illustrated in FIG. 24, each dark color layer 18 having a portion of the metal material subjected to darkening treatment (blackening treatment) may cover the rear surfaces of the first metal layers 21a and 22a. In this case, light is more likely to be regularly reflected at the surface, the side surfaces, and the rear surface of the dark color layer 18 and the surface and the rear surface of the primer layer 15. When light is regularly reflected at these portions, the contrast ratio may be increased at a specific wavelength due to interference of reflected light as indicated with a broken line A in FIG. 25. In this case, colors are more highly discernible at the wavelength corresponding to the high contrast ratio. Iridescent unevenness is thus more likely to occur due to a reflectance spectrum. In a known phenomenon, when an object is obliquely observed, the spectrum shifts toward the short wavelength as a result of an increase of an effective optical path length. In this case, a reflectance spectrum for the infrared region or the reflectance spectrum with high reflectivity shifts toward the short wavelength, and interferes with the visible light region. In this manner, due to thin-film interference, the wavelength shifts toward the short wavelength based on the angle of observation. Thus, when an object is obliquely observed, colors are more highly discernible than when an object is observed from the front.

As described above, the image-display-device multilayer body 70 formed from the wiring board 10 may be incorporated into a head mount display (smart glasses). In this case, as illustrated in FIG. 26, for example, the image-display-device multilayer bodies 70 may be attached to the frame 91 and incorporated into a head mount display 90. Also in this case, the contrast ratio may be increased at a specific wavelength due to light interference. In this case, as illustrated in FIG. 26 and FIG. 27, so-called iridescent unevenness R is more likely to occur due to the reflectance spectrum. The iridescent unevenness R is visually discerned by an observer that observes the attached head mount display without being visually discerned by a wearer of the head mount display 90. Particularly, the iridescent unevenness R is more likely to be visually discerned in the dark as an iridescent pattern by an observer.

In contrast, in the present modification example, the first direction wires 21 and the second direction wires 22 contain the black layers 21d and 22d containing resin. This structure can thus reduce reflection of light incident on the mesh wiring layers 20 from the substrate 11 and reflection at the side surfaces of the black layers 21d and 22d. This structure can thus reduce interference of reflected light. Thus, as indicated with a solid line B in FIG. 25, an increase of the contrast ratio at a specific wavelength can be reduced. This structure can thus reduce occurrence of so-called iridescent unevenness.

In this case, the black layers 21d and 22d may have a lower 5° specular reflectance at a wavelength of 700 nm than the dark color layer 18 does. This structure can reduce light reflection, and reduce an increase of the contrast ratio at a specific wavelength. This structure can thus reduce occurrence of so-called iridescent unevenness. In FIG. 25, the 5° specular reflectance of the dark color layer 18 is indicated by a dotted line C, and the 5° specular reflectance of the black layers 21d and 22d is indicated by a broken line D. The 5° specular reflectance is measured in the manner below. First, the wiring board 10 is prepared as a measurement sample. Thereafter, black tape (from Teraoka Seisakusho Co., Ltd.) is bonded to the rear surface of the measurement sample to reduce reflection at the rear surface of the measurement sample. The 5° specular reflectance is then measured with a UV-3100 spectrophotometer from Shimadzu Corporation.

The dark color layers 18 and the black layers 21d and 22d may have different 5° specular reflectance spectra in the visible wavelength range. In the present embodiment, the first direction wires 21 and the second direction wires 22 include both the dark color layers 18 and the black layers 21d and 22d. The dark color layers 18 and the black layers 21d and 22d have different reflectance spectra. The first direction wires 21 and the second direction wires 22 are less likely to allow interference in which the reflected light beams strengthen each other at a specific wavelength. Thus, the first direction wires 21 and the second direction wires 22 according to the present embodiment can reduce iridescent unevenness.

As described above, the wiring board 10 further includes the dark color layers 18 that cover the mesh wiring layers 20, and reflection of visible light at the surfaces of the dark color layers 18 can thus be reduced. The mesh wiring layers 20 covered with the dark color layers 18 are thus less visually discernible to the naked eye of an observer.

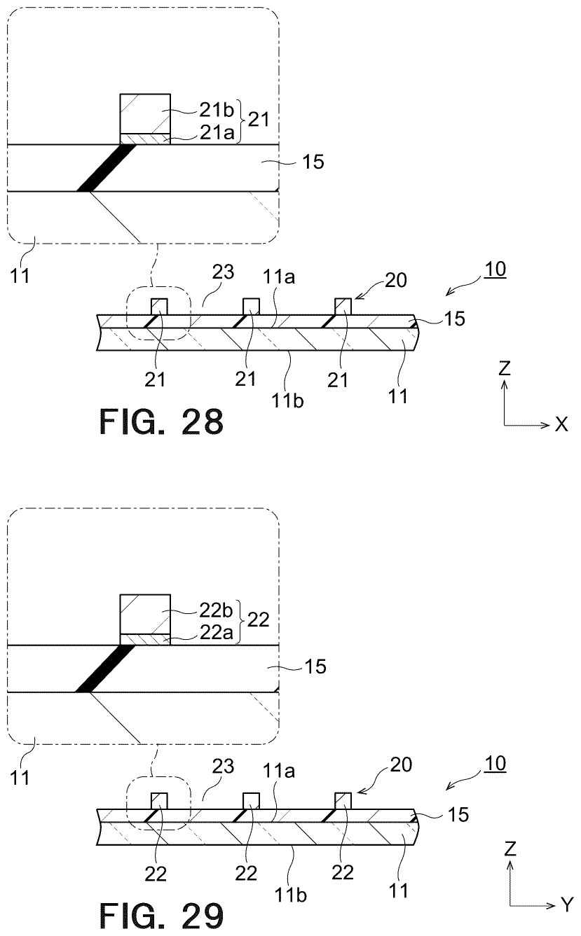

FIG. 28 and FIG. 29 illustrate a wiring board according to a third modification example of the second embodiment. The modification example illustrated in FIG. 28 and FIG. 29 differs from the embodiments illustrated in FIG. 13 to FIG. 27 in that the mesh wiring layers 20 do not include the black layers 21d and 22d, and other components are substantially the same as those in the embodiments illustrated in FIG. 13 to FIG. 27. In FIG. 28 and FIG. 29, like or corresponding components in the embodiments illustrated in FIG. 13 to FIG. 27 are denoted by like reference signs, and are not described in detail.

In the wiring board 10 illustrated in FIG. 28 and FIG. 29, the mesh wiring layers 20 do not include the black layers 21d and 22d disposed on the primer layer 15. More specifically, as illustrated in FIG. 28, each first direction wire 21 does not include the black layer 21d. In this case, each first direction wire 21 includes a first metal layer 21a disposed on the primer layer 15 and a second metal layer 21b disposed on the first metal layer 21a. As illustrated in FIG. 29, each second direction wire 22 does not include the black layer 22d. In this case, each second direction wire 22 includes a first metal layer 22a disposed on the primer layer 15, and a second metal layer 22b disposed on the first metal layer 22a.

In the present modification example, the primer layer 15 may be a layer with, for example, a dark color such as black. The primer layer 15 may contain a black coloring material. In this case, the primer layer 15 may contain a dye or a pigment as a black coloring material. More specifically, the primer layer 15 may contain a pigment such as carbon black or titanium black. The primer layer 15 formed from a dark color layer can reduce reflection of visible light that is incident on the mesh wiring layers 20 from the substrate 11. The mesh wiring layers 20 are thus less visually discernible to the naked eye.

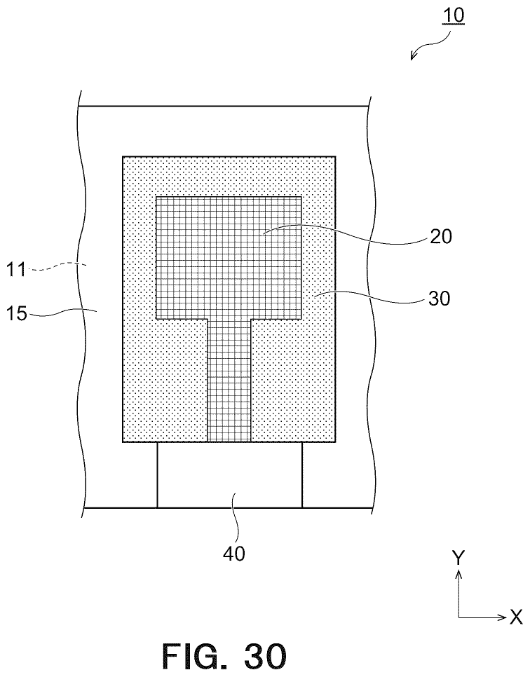

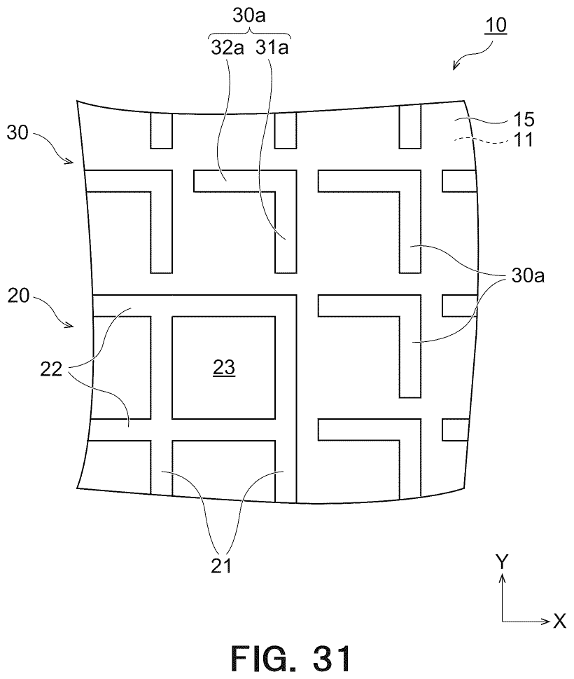

FIG. 30 and FIG. 31 illustrate a wiring board according to a fourth modification example of the second embodiment. As in the first modification example of the first embodiment, the modification example illustrated in FIG. 30 and FIG. 31 differs from the embodiments illustrated in FIG. 13 to FIG. 29 in that it includes dummy wiring layers 30 around the mesh wiring layers 20, and other components are substantially the same as those in the above embodiments illustrated in FIG. 13 to FIG. 29. In FIG. 30 and FIG. 31, like or corresponding components in the embodiments illustrated in FIG. 13 to FIG. 29 are denoted by like reference signs, and are not described in detail.

In the wiring board 10 illustrated in FIG. 30, a dummy wiring layer 30 is disposed around a mesh wiring layer 20. Unlike the mesh wiring layer 20, the dummy wiring layer 30 does not substantially function as an antenna.

As illustrated in FIG. 31, the dummy wiring layer 30 is formed from a pattern of dummy wires 30a having a predetermined unit pattern shape. More specifically, the dummy wiring layer 30 includes multiple dummy wires 30a of the same shape, and each of the dummy wires 30a is electrically separate from the corresponding mesh wiring layer 20 (the first direction wires 21 and the second direction wires 22). The multiple dummy wires 30a are arranged regularly throughout the entire area of the dummy wiring layer 30. The multiple dummy wires 30a are spaced apart from each other in the plan direction, and protrude upward from the substrate 11. More specifically, each dummy wire 30a is electrically separate from the corresponding mesh wiring layer 20, the corresponding feeding point 40, and other dummy wires 30a. Each dummy wire 30a has a substantially L shape in a plan view.

In this case, each dummy wire 30a has a shape that lacks a part of the unit pattern shape (refer to FIG. 16) of the above mesh wiring layers 20. Thus, the difference between the mesh wiring layers 20 and the dummy wiring layer 30 is less visually distinguishable, and the mesh wiring layers 20 disposed on the substrate 11 are thus less visually discernible.

As illustrated in FIG. 31, the dummy wires 30a extend parallel to the first direction wires 21 or the second direction wires 22. More specifically, each dummy wire 30a includes a first portion 31a extending parallel to the first direction wires 21, and a second portion 32a extending parallel to the second direction wires 22. The first portion 31a has a shape that lacks a part of each first direction wire 21. The second portion 32a has a shape that lacks a part of each second direction wire 22. Other portions of the first portion 31a and the second portion 32a are the same as those in the first direction wires 21 and the second direction wires 22, and thus are not described in detail. As described above, the dummy wires 30a extend parallel to the first direction wires 21 or the second direction wires 22, and thus, the mesh wiring layers 20 disposed on the substrate 11 are further less visually discernible. The aperture ratio of the dummy wiring layer 30 may be the same as or different from the aperture ratio of the mesh wiring layers 20. When the aperture ratio of the dummy wiring layer 30 is different from the aperture ratio of the mesh wiring layers 20, the aperture ratio of the dummy wiring layer 30 may be close to the aperture ratio of the mesh wiring layers 20.

In this manner, when the dummy wiring layer 30 electrically separate from each mesh wiring layer 20 is disposed around the mesh wiring layer 20, the outer periphery of the mesh wiring layer 20 is indistinguishable. The mesh wiring layers 20 on the surface of the image display device 60 are thus less visually discernible, and the mesh wiring layers 20 are less visually discernible to the naked eye of a user of the image display device 60.

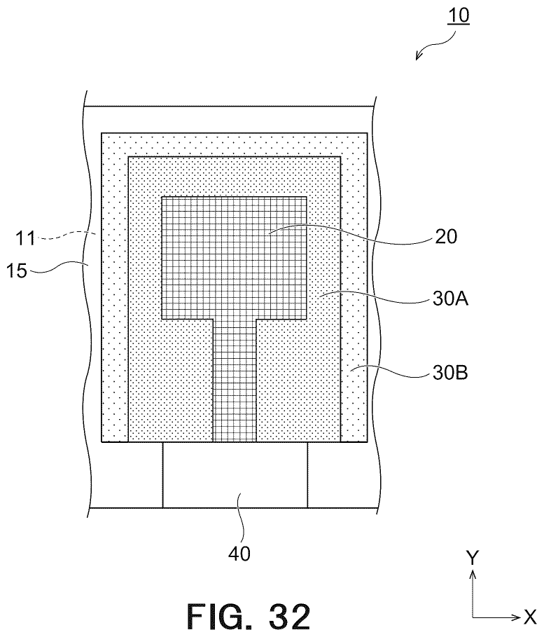

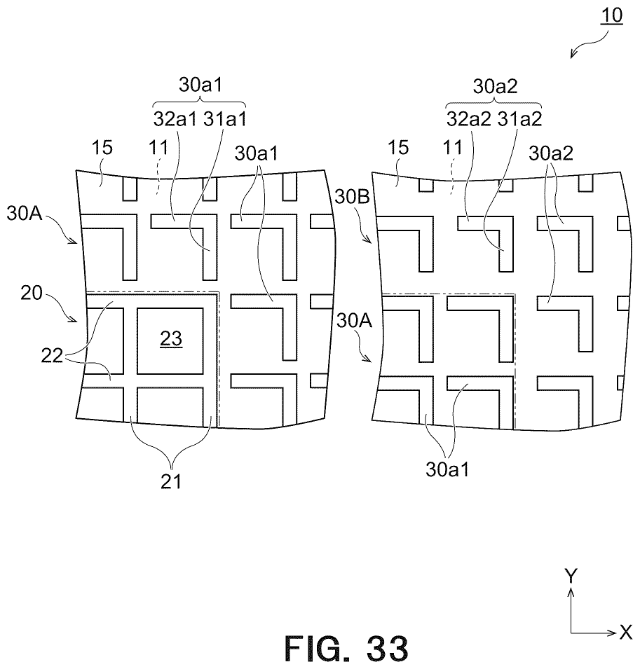

FIG. 32 and FIG. 33 illustrate a wiring board according to a fifth modification example of the second embodiment. As in the second modification example of the first embodiment, the modification example illustrated in FIG. 32 and FIG. 33 differs from the embodiments illustrated in FIG. 13 to FIG. 31 in that it includes two or more dummy wiring layers 30A and 30B having different aperture ratios and disposed around the mesh wiring layers 20, and other components are substantially the same as those in the embodiments illustrated in FIG. 13 to FIG. 31. In FIG. 32 and FIG. 33, like or corresponding components in the embodiments illustrated in FIG. 13 to FIG. 31 are denoted by like reference signs, and are not described in detail.

The wiring board 10 illustrated in FIG. 32 includes multiple (in this example, two) dummy wiring layers 30A and 30B (a first dummy wiring layer 30A and a second dummy wiring layer 30B) having different aperture ratios and disposed around the mesh wiring layers 20. More specifically, the first dummy wiring layer 30A is disposed around each mesh wiring layer 20, and the second dummy wiring layer 30B is disposed around the first dummy wiring layer 30A. Unlike the mesh wiring layers 20, the dummy wiring layers 30A and 30B do not substantially function as antennas.

As illustrated in FIG. 33, the first dummy wiring layer 30A includes a pattern of dummy wires 30a1 having a predetermined unit pattern shape. The second dummy wiring layer 30B includes a pattern of dummy wires 30a2 having a predetermined unit pattern shape. More specifically, the dummy wiring layers 30A and 30B include multiple dummy wires 30a1 and 30a2 of the same shapes, and each of the dummy wires 30a1 and 30a2 is electrically separate from the corresponding one of the mesh wiring layers 20. The dummy wires 30a1 and 30a2 are regularly arranged throughout the entire surfaces of the dummy wiring layers 30A and 30B. The dummy wires 30a1 and 30a2 are spaced apart from one another in the plan direction, and protrude upward from the substrate 11. Each of the dummy wires 30a1 and 30a2 is electrically separate from the corresponding mesh wiring layer 20, the corresponding feeding point 40, and the other dummy wires 30a1 and 30a2. Each of the dummy wires 30a1 and 30a2 has a substantially L shape in a plan view.

In this case, each of the dummy wires 30a1 and 30a2 has a shape that lacks a part of the unit pattern shape (refer to FIG. 16) of the above mesh wiring layers 20. The difference between the mesh wiring layers 20 and the first dummy wiring layer 30A and the difference between the first dummy wiring layer 30A and the second dummy wiring layer 30B are thus less visually distinguishable, and thus, the mesh wiring layers 20 disposed on the substrate 11 are less visually discernible. As illustrated in FIG. 33, the dummy wires 30a1 and 30a2 extend parallel to the first direction wires 21 or the second direction wires 22. More specifically, each of the dummy wires 30a1 includes a first portion 31a1 that extends parallel to the first direction wires 21, and a second portion 32a1 that extends parallel to the second direction wires 22. Each of the dummy wires 30a2 includes a first portion 31a2 that extends parallel to the first direction wires 21, and a second portion 32a2 that extends parallel to the second direction wires 22.

Each of the dummy wires 30a1 in the first dummy wiring layer 30A has a larger area than each of the dummy wires 30a2 in the second dummy wiring layer 30B. In this case, the wire width of each dummy wire 30a1 is the same as the wire width of each dummy wire 30a2, but the wire width of each dummy wire 30a1 may be greater than the wire width of each dummy wire 30a2. Other components of the dummy wires 30a1 and 30a2 are the same as the dummy wires 30a in the fourth modification example, and thus are not described in detail herein.

In the present modification example, the aperture ratios of each mesh wiring layer 20 and the two or more dummy wiring layers 30A and 30B may increase stepwise from the mesh wiring layer 20 toward the dummy wiring layers 30A and 30B, in a direction extending away from the mesh wiring layer 20. In other words, the dummy wiring layers may have aperture ratios that gradually increase from the dummy wiring layer located closer to the mesh wiring layer 20. In this case, the first dummy wiring layer 30A may have a larger aperture ratio than the mesh wiring layers 20. The second dummy wiring layer 30B may have a larger aperture ratio than the first dummy wiring layer 30A. This structure can make the outer peripheries of the mesh wiring layers 20 and the dummy wiring layers 30A and 30B further indistinguishable. The mesh wiring layers 20 on the surface of the image display device 60 are thus further less visually discernible.

Providing the dummy wiring layers 30A and 30B electrically separate from the mesh wiring layers 20 in this manner can make the outer peripheries of the mesh wiring layers 20 further indistinguishable. The mesh wiring layers 20 on the surface of the image display device 60 are thus further less visually discernible, and a user of the image display device 60 can less visually discern the mesh wiring layers 20 with the naked eye. Alternatively, three or more dummy wiring layers with different aperture ratios may be disposed around each mesh wiring layer 20.

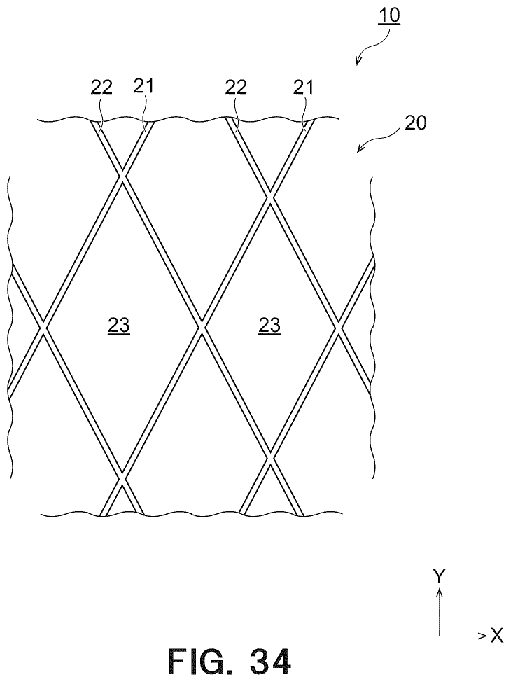

FIG. 34 illustrates a wiring board according to a sixth modification example of the second embodiment. As in the third modification example of the first embodiment, the modification example illustrated in FIG. 34 differs from the embodiments illustrated in FIG. 13 to FIG. 33 in the shape of the mesh wiring layers 20 in a plan view, and other components are substantially the same as those in the above embodiments illustrated in FIG. 13 to FIG. 33. In FIG. 34, like or corresponding components in the embodiments illustrated in FIG. 13 to FIG. 33 are denoted by like reference signs, and are not described in detail.

FIG. 34 is an enlarged plan view of a mesh wiring layer 20 according to a sixth modification example. In FIG. 34, the first direction wires 21 and the second direction wires 22 intersect obliquely (not orthogonally), and the apertures 23 have a rhombus shape in a plan view. Although the first direction wires 21 and the second direction wires 22 are parallel to neither the X direction nor the Y direction, either the first direction wires 21 or the second direction wires 22 may be parallel to the X direction or the Y direction.

Multiple components described in the embodiments and the modification examples may be combined as appropriate. Alternatively, one or more components may be eliminated from all the components described in the embodiments and the modification examples.

1. A wiring board, comprising:
a substrate having a first surface and a second surface positioned opposite to the first surface;
a primer layer disposed on the first surface of the substrate; and
a mesh wiring layer disposed on the primer layer,
wherein the substrate has transparency,
wherein the mesh wiring layer includes
a first dark color layer disposed on the primer layer,
a first metal layer disposed on the first dark color layer, and
a second metal layer disposed on the first metal layer, and
wherein the first dark color layer has a surface roughness Sa greater than or equal to 5 nm and less than or equal to 200 nm.

2. The wiring board according to claim 1, further comprising:
a second dark color layer covering the mesh wiring layer,
wherein the second dark color layer has a surface roughness Sa greater than or equal to 5 nm and less than or equal to 100 nm.

3. The wiring board according to claim 1,
wherein the first metal layer and the second metal layer have different crystal properties, and the second metal layer has a crystal property in which a diffraction angle 2θ of a (111) plane measured using Cu Kα radiation as an X-ray source is less than 43.4°.

4. The wiring board according to claim 1,
wherein the substrate has a dielectric loss tangent less than or equal to 0.002.

5. The wiring board according to claim 1,
wherein an increased rate of resistance of the mesh wiring layer is less than or equal to 20% when an operation including bending the wiring board 180° along a circumference of a cylinder with a diameter of 1 mm and then flattening the wiring board is performed 100 times.

6. The wiring board according to claim 1,
wherein the wiring board has a function of transmitting and receiving millimeter waves, and the mesh wiring layer serves as an array antenna.

7. The wiring board according to claim 1,
wherein at least one dummy wiring layer electrically separate from the mesh wiring layer is disposed around the mesh wiring layer.

8. The wiring board according to claim 7,
wherein the at least one dummy wiring layer includes a plurality of dummy wiring layers, and the mesh wiring layer and the plurality of dummy wiring layers have aperture ratios that increase stepwise from the mesh wiring layer toward the plurality of dummy wiring layers, in a direction extending away from the mesh wiring layer.

9. An image display device, comprising:
the wiring board according to claim 1; and
a display device laminated on the wiring board.

10. A wiring board, comprising:
a substrate having a first surface and a second surface positioned opposite to the first surface; and
a mesh wiring layer disposed on the first surface of the substrate,
wherein the substrate has transparency,
wherein the mesh wiring layer includes a wire,
wherein the wire includes
a black layer containing resin,
a first metal layer disposed on the black layer, and
a second metal layer disposed on the first metal layer, and
wherein the wire has a wire width less than or equal to 5.0 μm.

11. The wiring board according to claim 10, further comprising:
a primer layer disposed between the substrate and the mesh wiring layer.

12. The wiring board according to claim 10,
wherein the black layer has a thickness greater than or equal to 0.2 μm and less than or equal to 1.0 μm.

13. The wiring board according to claim 10,
wherein the black layer contains a dye or a pigment.

14. The wiring board according to claim 10,
wherein the first metal layer and the second metal layer have different crystal properties, and the second metal layer has a crystal property in which a diffraction angle 2θ of a (111) plane measured using Cu Kα radiation as an X-ray source is less than 43.4°.

15. The wiring board according to claim 10,
wherein the substrate has a dielectric loss tangent less than or equal to 0.002.

16. The wiring board according to claim 10,
wherein an increased rate of resistance of the mesh wiring layer is less than or equal to 20% when an operation including bending the wiring board 180° along a circumference of a cylinder with a diameter of 1 mm and then flattening the wiring board is performed 100 times.

17. The wiring board according to claim 10,
wherein the wiring board has a function of transmitting and receiving millimeter waves, and the mesh wiring layer serves as an array antenna.

18. The wiring board according to claim 10,
wherein at least one dummy wiring layer electrically separate from the mesh wiring layer is disposed around the mesh wiring layer.

19. The wiring board according to claim 18,
wherein the at least one dummy wiring layer includes a plurality of dummy wiring layers, and the mesh wiring layer and the plurality of dummy wiring layers have aperture ratios that increase stepwise from the mesh wiring layer toward the plurality of dummy wiring layers, in a direction extending away from the mesh wiring layer.

20. The wiring board according to claim 10, further comprising:
a dark color layer covering the mesh wiring layer.

21. The wiring board according to claim 20,
wherein the black layer has a lower 5° specular reflectance at a wavelength of 700 nm than the dark color layer does.

22. The wiring board according to claim 20,
wherein the dark color layer and the black layer have different 5° specular reflectance spectra in a visible wavelength range.

23. A wiring board, comprising:
a substrate having a first surface and a second surface positioned opposite to the first surface;
a primer layer disposed on the first surface of the substrate; and
a mesh wiring layer disposed on the primer layer,
wherein the substrate has transparency,
wherein the primer layer is a dark color layer,
wherein the mesh wiring layer includes a wire, and
wherein the wire includes
a first metal layer disposed on the primer layer, and
a second metal layer disposed on the first metal layer.

24. An image display device, comprising:
the wiring board according to claim 10 and
a display device laminated on the wiring board.
